(19) United States
(12) Patent Application Publication
(10) Pub. No.: US 2026/0369865 A1
(43) Pub. Date: Nov. 19, 2026

(54) ELECTRONIC DEVICE INCLUDING ELECTROSTATIC DISCHARGE ELEMENT HAVING MIM STRUCTURE

(71) Applicant: Samsung Electronics Co., Ltd., Suwon-si (KR)

(72) Inventors: Minbeom KO, Suwon-si (KR); Woonghae CHOI, Suwon-si (KR); Kiwoong CHA, Suwon-si (KR); Cheolgu JO, Suwon-si (KR); Seongho SON, Suwon-si (KR); Hojung NAM, Suwon-si (KR); Hajin KIM, Suwon-si (KR); Yeojin KIM, Suwon-si (KR); Kyungil SEO, Suwon-si (KR); Soonho HWANG, Suwon-si (KR)

(21) Appl. No.: 19/552,458

(22) Filed: Feb. 27, 2026

Related U.S. Application Data
(63) Continuation of application No. PCT/KR2026/002086, filed on Feb. 4, 2026.

(30) Foreign Application Priority Data
May 13, 2025 (KR) 10-2025-0062006
Jun. 9, 2025 (KR) 10-2025-0075010

(51) Int. Cl. H01Q 1/22; H01Q 5/30; H03H 7/01

(52) U.S. Cl. CPC H01Q 1/22; H01Q 5/30; H03H 7/0138

(57) ABSTRACT

An electronic device includes wireless communication circuitry, a frame including a conductive portion, a first connecting member, including conductive layers and non-conductive layers alternatively stacked with the conductive layers, electrically connected to the wireless communication circuitry and the conductive portion, respectively, and a second connecting member, electrically connected to the first connecting member and a ground, respectively. The first connecting member includes at least one first conductive layer electrically connected to the wireless communication circuitry, at least one second conductive layer, electrically connected to the conductive portion and electrically connected to the first conductive layer, and at least one third conductive layer electrically connected to the ground through the second connecting member. The plurality of conductive layers of the first connecting member are configured to function as a first capacitor to block static electricity flowing through the conductive portion.

### CROSS-REFERENCE TO RELATED APPLICATION(S)

This application is a continuation application, claiming priority under 35 U.S.C. § 365(c), of an International application No. PCT/KR2026/002086, filed on Feb. 4, 2026, which is based on and claims the benefit of a Korean patent application number 10-2025-0062006, filed on May 13, 2025, in the Ministry of Intellectual Property, and of a Korean patent application number 10-2025-0075010, filed on Jun. 9, 2025, in the Ministry of Intellectual Property, the disclosure of each of which is incorporated by reference herein in its entirety.

### TECHNICAL FIELD

The disclosure relates to an electronic device including an electrostatic discharge element having a metal-insulator-metal (MIM) structure.

### BACKGROUND ART

An electronic device may include a frame forming at least a portion of a side surface of the electronic device. The frame may include a conductive portion configured to function as an antenna radiator. The conductive portion may be exposed to the outside of the electronic device. The electronic device may include an electrostatic discharge element for discharging static electricity flowing through the conductive portion. A metal-insulator-metal (MIM) structure may be referred to as a structure in which a metal-insulator-metal is stacked.

The above information is presented as background information only to assist with an understanding of the disclosure. No determination has been made, and no assertion is made, as to whether any of the above might be applicable as prior art with regard to the disclosure.

### DISCLOSURE

### Technical Solution

Aspects of the disclosure are to address at least the above-mentioned problems and/or disadvantages and to provide at least the advantages described below. Accordingly, an aspect of the disclosure is to provide an electronic device including an electrostatic discharge element having a metal-insulator-metal (MIM) structure.

Additional aspects will be set forth in part in the description which follows and, in part, will be apparent from the description, or may be learned by practice of the presented embodiments.

In accordance with an aspect of the disclosure, an electronic device is provided. The electronic device may include wireless communication circuitry. The electronic device may include a frame including a conductive portion, forming, a portion of a periphery of the electronic device, configured to function as an antenna radiator. The electronic device may include a first connecting member, including conductive layers and non-conductive layers alternatively stacked with the conductive layers, electrically connected to the wireless communication circuitry and the conductive portion, respectively. The electronic device may include a second connecting member, electrically connected to the first connecting member and a ground of the electronic device, respectively. The first connecting member may include at least one first conductive layer electrically connected to the wireless communication circuitry, at least one second conductive layer, electrically connected to the conductive portion and the at least one first conductive layer, respectively, and at least one third conductive layer electrically connected to the ground through the second connecting member. The first connecting member may be configured to function as a first capacitor to block static electricity flowing through the conductive portion.

In accordance with another aspect of the disclosure, an electronic device is provided. The electronic device may include wireless communication circuitry. The electronic device may include a frame including a conductive portion that forms at least a portion of a periphery of the electronic device and is configured to function as an antenna radiator. The electronic device may include a support, at least partially surrounded by the frame, configured to function as a ground of the electronic device. The electronic device may include a first connecting member, including conductive layers and non-conductive layers alternating with each other, electrically connected to the wireless communication circuitry and the conductive portion, respectively. The electronic device may include a second connecting member, electrically connected to the first connecting member and the support, respectively. The first connecting member may include at least one first conductive layer electrically connected to the wireless communication circuitry, and at least one second conductive layer, electrically connected to the conductive portion and the at least one first conductive layer, respectively. The electronic device may include at least one third conductive layer, inserted into the first connecting member, electrically connected to the ground through the second connecting member. The at least one first conductive layer and the at least one second conductive layer may provide at least a portion of an electrical path between the wireless communication circuitry and the conductive portion. The first connecting member may be configured to function as a first capacitor to block static electricity flowing through the conductive portion.

Other aspects, advantages, and salient features of the disclosure will become apparent to those skilled in the art from the following detailed description, which, taken in conjunction with the annexed drawings, discloses various embodiments of the disclosure.

### DESCRIPTION OF THE DRAWINGS

The above and other aspects, features, and advantages of certain embodiments of the disclosure will be more apparent from the following description taken in conjunction with the accompanying drawings, in which:

FIG. 1 is a block diagram of an electronic device in a network environment according to an embodiment of the disclosure;

FIG. 2 is a block diagram of an electronic device according to an embodiment of the disclosure;

FIG. 3 illustrates an electronic device according to an embodiment of the disclosure;

FIG. 4 is circuitry for electrostatic discharge, according to a comparative example;

FIG. 5 is a graph indicating a communication performance of an electronic device according to a comparative example;

FIG. 6 is a cross-sectional view of a metal-insulator-metal (MIM) element according to an embodiment of the disclosure;

FIG. 7 schematically illustrates a first connecting member according to an embodiment of the disclosure;

FIG. 8 illustrates a first connecting member in contact with an antenna contact according to an embodiment of the disclosure;

FIG. 9 illustrates various examples of a second connecting member according to an embodiment of the disclosure;

FIG. 10 is a plan view of a first connecting member according to an embodiment of the disclosure;

FIG. 11 is equivalent circuitry of an electronic device including a first connecting member, according to an embodiment of the disclosure;

FIG. 12 is a graph indicating an S-parameter of an antenna according to frequency in the circuitry according to the comparative example of FIG. 4;

FIG. 13 is a graph indicating an S-parameter of an antenna according to frequency in the circuitry of FIG. 11;

FIG. 14 is a graph indicating a total radiation efficiency of a second antenna including a second antenna radiator adjacent to a first antenna radiator;

FIG. 15 is a graph indicating an S-parameter of an antenna according to an inductance value of an inductor of a second connecting member;

FIG. 16 is a graph indicating a total radiation efficiency of an antenna according to an inductance value of an inductor of a second connecting member;

FIG. 17 is a graph indicating a transmission line pulse (TLP) test result according to an embodiment of the disclosure;

FIG. 18 illustrates an electronic device including a switch circuit according to an embodiment of the disclosure;

FIGS. 19, 20, 21, 22, and 23 illustrate various examples of a first connecting member according to various embodiments of the disclosure; and

FIGS. 24, 25, and 26 illustrate examples of a first connecting member including at least one fourth conductive layer according to various embodiments of the disclosure.

Throughout the drawings, it should be noted that like reference numbers are used to depict the same or similar elements, features, and structures.

### MODE FOR INVENTION

The following description with reference to the accompanying drawings is provided to assist in a comprehensive understanding of various embodiments of the disclosure as defined by the claims and their equivalents. It includes various specific details to assist in that understanding but these are to be regarded as merely exemplary. Accordingly, those of ordinary skill in the art will recognize that various changes and modifications of the various embodiments described herein can be made without departing from the scope and spirit of the disclosure. In addition, descriptions of well-known functions and constructions may be omitted for clarity and conciseness.

The terms and words used in the following description and claims are not limited to the bibliographical meanings, but, are merely used by the inventor to enable a clear and consistent understanding of the disclosure. Accordingly, it should be apparent to those skilled in the art that the following description of various embodiments of the disclosure is provided for illustration purpose only and not for the purpose of limiting the disclosure as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces.

It should be appreciated that the blocks in each flowchart and combinations of the flowcharts may be performed by one or more computer programs which include instructions. The entirety of the one or more computer programs may be stored in a single memory device or the one or more computer programs may be divided with different portions stored in different multiple memory devices.

Any of the functions or operations described herein can be processed by one processor or a combination of processors. The one processor or the combination of processors is circuitry performing processing and includes circuitry like an application processor (AP, e.g., a central processing unit (CPU)), a communication processor (CP, e.g., a modem), a graphics processing unit (GPU), a neural processing unit (NPU) (e.g., an artificial intelligence (AI) chip), a wireless fidelity (Wi-Fi) chip, a Bluetooth® chip, a global positioning system (GPS) chip, a near field communication (NFC) chip, connectivity chips, a sensor controller, a touch controller, a finger-print sensor controller, a display driver integrated circuit (IC), an audio CODEC chip, a universal serial bus (USB) controller, a camera controller, an image processing IC, a microprocessor unit (MPU), a system on chip (SoC), an IC, or the like.

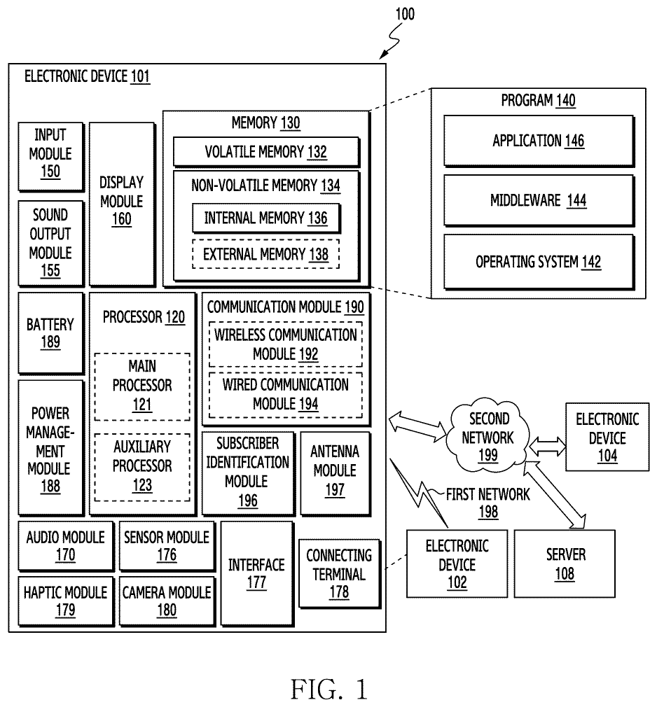

FIG. 1 is a block diagram illustrating an electronic device 101 in a network environment 100 according to various embodiments.

Referring to FIG. 1, the electronic device 101 in the network environment 100 may communicate with an electronic device 102 via a first network 198 (e.g., a short-range wireless communication network), or at least one of an electronic device 104 or a server 108 via a second network 199 (e.g., a long-range wireless communication network). According to an embodiment, the electronic device 101 may communicate with the electronic device 104 via the server 108. According to an embodiment, the electronic device 101 may include a processor 120, memory 130, an input module 150, a sound output module 155, a display module 160, an audio module 170, a sensor module 176, an interface 177, a connecting terminal 178, a haptic module 179, a camera module 180, a power management module 188, a battery 189, a communication module 190, a subscriber identification module (SIM) 196, or an antenna module 197. In some embodiments, at least one of the components (e.g., the connecting terminal 178) may be omitted from the electronic device 101, or one or more other components may be added in the electronic device 101. In some embodiments, some of the components (e.g., the sensor module 176, the camera module 180, or the antenna module 197) may be implemented as a single component (e.g., the display module 160).

The processor 120 may execute, for example, software (e.g., a program 140) to control at least one other component (e.g., a hardware or software component) of the electronic device 101 coupled with the processor 120, and may perform various data processing or computation. According to an embodiment, as at least part of the data processing or computation, the processor 120 may store a command or data received from another component (e.g., the sensor module 176 or the communication module 190) in volatile memory 132, process the command or the data stored in the volatile memory 132, and store resulting data in non-volatile memory 134. According to an embodiment, the processor 120 may include a main processor 121 (e.g., a central processing unit (CPU) or an application processor (AP)), or an auxiliary processor 123 (e.g., a graphics processing unit (GPU), a neural processing unit (NPU), an image signal processor (ISP), a sensor hub processor, or a communication processor (CP)) that is operable independently from, or in conjunction with, the main processor 121. For example, when the electronic device 101 includes the main processor 121 and the auxiliary processor 123, the auxiliary processor 123 may be adapted to consume less power than the main processor 121, or to be specific to a specified function. The auxiliary processor 123 may be implemented as separate from, or as part of the main processor 121.

The auxiliary processor 123 may control at least some of functions or states related to at least one component (e.g., the display module 160, the sensor module 176, or the communication module 190) among the components of the electronic device 101, instead of the main processor 121 while the main processor 121 is in an inactive (e.g., sleep) state, or together with the main processor 121 while the main processor 121 is in an active state (e.g., executing an application). According to an embodiment, the auxiliary processor 123 (e.g., an image signal processor or a communication processor) may be implemented as part of another component (e.g., the camera module 180 or the communication module 190) functionally related to the auxiliary processor 123. According to an embodiment, the auxiliary processor 123 (e.g., the neural processing unit) may include a hardware structure specified for artificial intelligence model processing. An artificial intelligence model may be generated by machine learning. Such learning may be performed, e.g., by the electronic device 101 where the artificial intelligence is performed or via a separate server (e.g., the server 108). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted Boltzmann machine (RBM), a deep belief network (DBN), a bidirectional recurrent deep neural network (BRDNN), deep Q-network or a combination of two or more thereof but is not limited thereto. The artificial intelligence model may, additionally or alternatively, include a software structure other than the hardware structure.

The memory 130 may store various data used by at least one component (e.g., the processor 120 or the sensor module 176) of the electronic device 101. The various data may include, for example, software (e.g., the program 140) and input data or output data for a command related thereto. The memory 130 may include the volatile memory 132 or the non-volatile memory 134.

The program 140 may be stored in the memory 130 as software, and may include, for example, an operating system (OS) 142, middleware 144, or an application 146.

The input module 150 may receive a command or data to be used by another component (e.g., the processor 120) of the electronic device 101, from the outside (e.g., a user) of the electronic device 101. The input module 150 may include, for example, a microphone, a mouse, a keyboard, a key (e.g., a button), or a digital pen (e.g., a stylus pen).

The sound output module 155 may output sound signals to the outside of the electronic device 101. The sound output module 155 may include, for example, a speaker or a receiver. The speaker may be used for general purposes, such as playing multimedia or playing record. The receiver may be used for receiving incoming calls. According to an embodiment, the receiver may be implemented as separate from, or as part of the speaker.

The display module 160 may visually provide information to the outside (e.g., a user) of the electronic device 101. The display module 160 may include, for example, a display, a hologram device, or a projector and control circuitry to control a corresponding one of the display, hologram device, and projector. According to an embodiment, the display module 160 may include a touch sensor adapted to detect a touch, or a pressure sensor adapted to measure the intensity of force incurred by the touch.

The audio module 170 may convert a sound into an electrical signal and vice versa. According to an embodiment, the audio module 170 may obtain the sound via the input module 150, or output the sound via the sound output module 155 or a headphone of an external electronic device (e.g., an electronic device 102) directly (e.g., wiredly) or wirelessly coupled with the electronic device 101.

The sensor module 176 may detect an operational state (e.g., power or temperature) of the electronic device 101 or an environmental state (e.g., a state of a user) external to the electronic device 101, and then generate an electrical signal or data value corresponding to the detected state. According to an embodiment, the sensor module 176 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the electronic device 102) directly (e.g., wiredly) or wirelessly. According to an embodiment, the interface 177 may include, for example, a high definition multimedia interface (HDMI), a universal serial bus (USB) interface, a secure digital (SD) card interface, or an audio interface.

A connecting terminal 178 may include a connector via which the electronic device 101 may be physically connected with the external electronic device (e.g., the electronic device 102). According to an embodiment, the connecting terminal 178 may include, for example, an HDMI connector, a USB connector, an SD card connector, or an audio connector (e.g., a headphone connector).

The haptic module 179 may convert an electrical signal into a mechanical stimulus (e.g., a vibration or a movement) or electrical stimulus which may be recognized by a user via his tactile sensation or kinesthetic sensation. According to an embodiment, the haptic module 179 may include, for example, a motor, a piezoelectric element, or an electric stimulator.

The camera module 180 may capture a still image or moving images. According to an embodiment, the camera module 180 may include one or more lenses, image sensors, image signal processors, or flashes.

The power management module 188 may manage power supplied to the electronic device 101. According to an embodiment, the power management module 188 may be implemented as at least part of, for example, a power management integrated circuit (PMIC).

The battery 189 may supply power to at least one component of the electronic device 101. According to an embodiment, the battery 189 may include, for example, a primary cell which is not rechargeable, a secondary cell which is rechargeable, or a fuel cell.

The communication module 190 may support establishing a direct (e.g., wired) communication channel or a wireless communication channel between the electronic device 101 and the external electronic device (e.g., the electronic device 102, the electronic device 104, or the server 108) and performing communication via the established communication channel. The communication module 190 may include one or more communication processors that are operable independently from the processor 120 (e.g., the application processor (AP)) and supports a direct (e.g., wired) communication or a wireless communication. According to an embodiment, the communication module 190 may include a wireless communication module 192 (e.g., a cellular communication module, a short-range wireless communication module, or a global navigation satellite system (GNSS) communication module) or a wired communication module 194 (e.g., a local area network (LAN) communication module or a power line communication (PLC) module). A corresponding one of these communication modules may communicate with the external electronic device via the first network 198 (e.g., a short-range communication network, such as Bluetooth™ wireless-fidelity (Wi-Fi) direct, or infrared data association (IrDA)) or the second network 199 (e.g., a long-range communication network, such as a legacy cellular network, a fifth generation (5G) network, a next-generation communication network, the Internet, or a computer network (e.g., LAN or wide area network (WAN)). These various types of communication modules may be implemented as a single component (e.g., a single chip), or may be implemented as multi components (e.g., multi chips) separate from each other. The wireless communication module 192 may identify and authenticate the electronic device 101 in a communication network, such as the first network 198 or the second network 199, using subscriber information (e.g., international mobile subscriber identity (IMSI)) stored in the subscriber identification module 196.

The wireless communication module 192 may support a 5G network, after a fourth generation (4G) network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 192 may support a high-frequency band (e.g., the millimeter-wave (mmWave) band) to achieve, e.g., a high data transmission rate. The wireless communication module 192 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The wireless communication module 192 may support various requirements specified in the electronic device 101, an external electronic device (e.g., the electronic device 104), or a network system (e.g., the second network 199). According to an embodiment, the wireless communication module 192 may support a peak data rate (e.g., 20 Gbps or more) for implementing eMBB, loss coverage (e.g., 164 dB or less) for implementing mMTC, or user plane (U-plane) latency (e.g., 0.5 ms or less for each of downlink (DL) and uplink (UL), or a round trip of Ims or less) for implementing URLLC.

The antenna module 197 may transmit or receive a signal or power to or from the outside (e.g., the external electronic device) of the electronic device 101. According to an embodiment, the antenna module 197 may include an antenna including a radiating element composed of a conductive material or a conductive pattern formed in or on a substrate (e.g., a printed circuit board (PCB)). According to an embodiment, the antenna module 197 may include a plurality of antennas (e.g., array antennas). In such a case, at least one antenna appropriate for a communication scheme used in the communication network, such as the first network 198 or the second network 199, may be selected, for example, by the communication module 190 (e.g., the wireless communication module 192) from the plurality of antennas. The signal or the power may then be transmitted or received between the communication module 190 and the external electronic device via the selected at least one antenna. According to an embodiment, another component (e.g., a radio frequency integrated circuit (RFIC)) other than the radiating element may be additionally formed as part of the antenna module 197.

According to various embodiments, the antenna module 197 may form a mmWave antenna module. According to an embodiment, the mmWave antenna module may include a printed circuit board, an RFIC disposed on a first surface (e.g., the bottom surface) of the printed circuit board, or adjacent to the first surface and capable of supporting a designated high-frequency band (e.g., the mmWave band), and a plurality of antennas (e.g., array antennas) disposed on a second surface (e.g., the top or a side surface) of the printed circuit board, or adjacent to the second surface and capable of transmitting or receiving signals of the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, commands or data may be transmitted or received between the electronic device 101 and the external electronic device 104 via the server 108 coupled with the second network 199. Each of the electronic devices 102 or 104 may be a device of a same type as, or a different type, from the electronic device 101. According to an embodiment, all or some of operations to be executed at the electronic device 101 may be executed at one or more of the external electronic devices 102, 104, or 108. For example, if the electronic device 101 should perform a function or a service automatically, or in response to a request from a user or another device, the electronic device 101, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 101. The electronic device 101 may provide the outcome, with or without further processing of the outcome, as at least part of a reply to the request. To that end, a cloud computing, distributed computing, mobile edge computing (MEC), or client-server computing technology may be used, for example. The electronic device 101 may provide ultra low-latency services using, e.g., distributed computing or mobile edge computing. In another embodiment, the external electronic device 104 may include an internet-of-things (IoT) device. The server 108 may be an intelligent server using machine learning and/or a neural network. According to an embodiment, the external electronic device 104 or the server 108 may be included in the second network 199. The electronic device 101 may be applied to intelligent services (e.g., smart home, smart city, smart car, or healthcare) based on 5G communication technology or IoT-related technology.

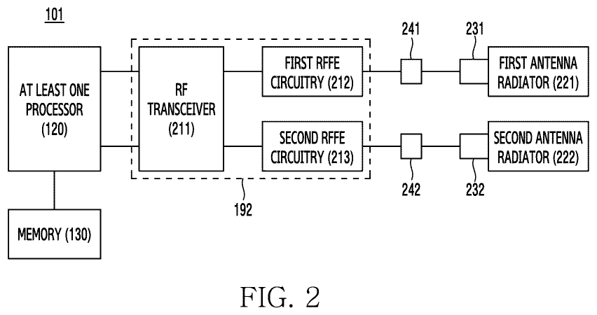

FIG. 2 is a block diagram of an electronic device according to an embodiment of the disclosure.

Referring to FIG. 2, an electronic device (e.g., the electronic device 101 of FIG. 1) according to an embodiment may include at least one processor (e.g., the processor 120 of FIG. 1), wireless communication circuitry (e.g., the wireless communication module 192 of FIG. 1), and at least one antenna radiator (e.g., a first antenna radiator 221 and/or a second antenna radiator 222).

According to an embodiment, the at least one processor 120 may include processing circuitry. The at least one processor 120 may include an application processor (AP) (e.g., a central processing unit (CPU)) and/or a communication processor (CP) (e.g., a modem), but is not limited thereto. The at least one processor 120 may include a graphics processing unit (e.g., a GPU), a neural processing unit (NPU) (e.g., an artificial intelligence (AI) chip), a wireless-fidelity (Wi-Fi) chip, a Bluetooth® chip, a global positioning system (GPS) chip, a near field communication (NFC) chip, connectivity chips, a sensor controller, a touch controller, a finger-print sensor controller, a display drive integrated (DDI) circuit, an audio CODEC chip, a universal serial bus (USB) controller, a camera controller, an image processing IC, a microprocessor unit (MPU), a system on chip (SoC), an integrated circuit (IC), or circuitry similar thereto.

According to an embodiment, memory (e.g., the memory 130 of FIG. 1) may include one or more storage media storing instructions. Any function or operation described in the disclosure may be performed by execution of instructions by the at least one processor 120. A combination of a block and a flow chart of each flow chart in the disclosure may be performed by one or more computer programs including computer-executable instructions. All of the one or more computer programs may be stored in single memory 130, or the one or more computer programs may be divided into different portions stored in different multiple memories 130.

The electronic device 101 according to an embodiment may include wireless communication circuitry 192. The wireless communication circuitry 192 may include a radio frequency (RF) transceiver 211 and RF front end (RFFE) circuitry (e.g., first RFFE circuitry 212 and/or second RFFE circuitry 213).

According to an embodiment, the at least one processor 120 may generate a baseband signal. The baseband signal may be a digital signal. The at least one processor 120 may control the RF transceiver 211 to transmit the baseband signal through the antenna radiator. For example, the at least one processor 120 may control the RF transceiver 211 such that the baseband signal is transmitted in a frequency band capable of communicating with an external electronic device.

According to an embodiment, the RF transceiver 211 may be implemented as a single chip (e.g., an RFIC chip) or as a portion of a single package. The RF transceiver 211 may be configured to modulate the baseband signal generated by the at least one processor 120 into an analog signal and convert the baseband signal into an RF frequency band. The RF transceiver 211 may be configured to convert an RF signal into a baseband signal and demodulate the RF signal into a digital signal such that the RF signal received from the external electronic device through at least one radiator may be processed by the at least one processor 120.

For example, the RF transceiver 211 may include a digital to analog converter (DAC) for converting a digital signal into an analog signal. For example, the RF transceiver 211 may include a mixer and an oscillator (e.g., a local oscillator (LO)) for up-conversion. For example, the RF transceiver 211 may include an analog to digital converter (ADC) for converting an analog signal into a digital signal. For example, the RF transceiver 211 may include a mixer and an oscillator for down-conversion.

According to an embodiment, the RFFE circuitry may include a plurality of components electrically connected between the RF transceiver 211 and the at least one antenna radiator. For example, the RFFE circuitry may include components such as a coupler, a filter, an RF switch, a power amplifier (PA), a low noise amplifier (LNA), a switch circuit 1810, and/or a duplexer. However, the components of the RFFE circuitry are not limited to the above-described components. The RFFE circuitry may include the first RFFE circuitry 212 electrically connected between the RF transceiver 211 and a first antenna radiator, and the second RFFE circuitry 213 electrically connected between the RF transceiver 211 and a second antenna radiator. In FIG. 2, each of the first RFFE circuitry 212 and the second RFFE circuitry 213 is illustrated as separate blocks, and the disclosure is not limited thereto. For example, the first RFFE circuitry 212 and the second RFFE circuitry 213 may also be included in a single package.

According to an embodiment, the wireless communication circuitry 192 may be configured to communicate with an external electronic device using the at least one antenna radiator. The at least one antenna radiator may include a feed point at which a feed signal from the wireless communication circuitry 192 is provided and a ground point connected to a ground of the electronic device 101.

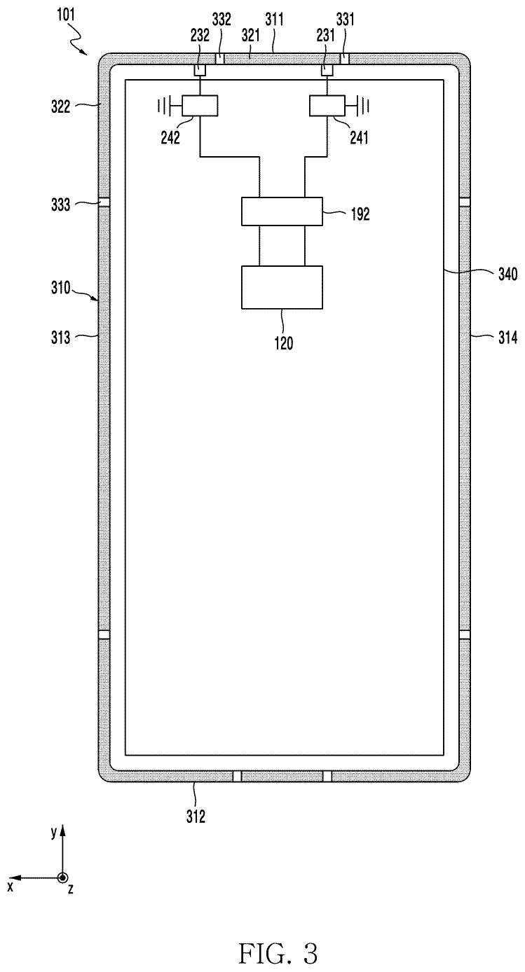

For example, the at least one antenna radiator, which is a physical component of an antenna, may be configured to radiate and/or receive an electromagnetic wave by being fed from the wireless communication circuitry 192. The at least one antenna radiator may be configured to radiate RF signals to the outside of the electronic device 101 based on the feed from the wireless communication circuitry 192. A type and performance of the antenna may be based on a physical structure of the at least one antenna radiator. The electronic device 101 may include at least one antenna radiators of various types. For example, the at least one antenna radiator may correspond to a portion (e.g., a first conductive portion 321 and/or a second conductive portion 322 of FIG. 3) of a frame (e.g., a frame 310 of FIG. 3) that forms at least a portion of a periphery of the electronic device 101.

For example, the at least one antenna radiator may include the first antenna radiator 221 and/or the second antenna radiator 222. The first antenna radiator 221 may be referred to as an antenna radiator for transmitting and/or receiving a first RF signal on a first frequency band, and the second antenna radiator 222 may be referred to as an antenna radiator for transmitting and/or receiving a second RF signal on a second frequency band. The first frequency band and the second frequency band may also be different from each other, or at least partially overlap each other. For example, according to a structure, a size, a communication performance, and a purpose of the electronic device 101, the first frequency band and the second frequency band may also be different or at least partially overlap.

For example, the electronic device 101 may transmit and/or receive RF signals on a low band using the first antenna radiator 221, and may transmit and/or receive RF signals for Wi-Fi, GPS, or ultra-wideband (UWB) using the second antenna radiator 222. For example, the electronic device 101 may perform a multiple-input and multiple-output (MIMO) operation using the first antenna radiator 221 and the second antenna radiator 222. According to an embodiment, the first antenna radiator 221 may be referred to as a first conductive portion (e.g., the first conductive portion 321 of FIG. 3), and the second antenna radiator 222 may be referred to as a second conductive portion (e.g., the second conductive portion 322 of FIG. 3). The first conductive portion 321 and the second conductive portion 322 will be described later with reference to FIG. 3.

According to an embodiment, the wireless communication circuitry 192 may be configured to communicate with an external electronic device by feeding a feed point of the at least one antenna radiator. When the feed point of the at least one antenna radiator is fed, a current (e.g., a radiation current) may flow along the at least one antenna radiator. The current may form an electromagnetic wave around the at least one antenna radiator, and RF signals may be radiated or received through the electromagnetic wave.

The electronic device 101 according to an embodiment may include an electrical path electrically connecting the wireless communication circuitry 192 and the at least one antenna radiator. For example, the electronic device 101 may include a first electrical path electrically connecting a first antenna contact 231 electrically connected to the first antenna radiator 221 and the wireless communication circuitry 192, and a second electrical path electrically connecting a second antenna contact 232 electrically connected to the second antenna radiator 222 and the wireless communication circuitry 192. For example, the first antenna contact 231 and the second antenna contact 232 may include a conductive clip or a conductive pin, but are not limited thereto.

The electronic device 101 according to an embodiment may include an electrostatic discharge (ESD) element for discharging static electricity flowing from the outside of the electronic device 101 through the at least one antenna radiator. The electrostatic discharge element may be configured to block static electricity flowing through the at least one antenna radiator. The electrostatic discharge element may be electrically connected to an electrical path between the wireless communication circuitry 192 and the at least one antenna radiator such that static electricity having a high voltage flows to the ground of the electronic device 101 without flowing into the wireless communication circuitry 192. For example, the electronic device 101 may include a first electrostatic discharge element 241 electrically connected to the first electrical path and/or a second electrostatic discharge element 242 electrically connected to the second electrical path.

Hereinafter, a structure of the electronic device 101 including the electrostatic discharge element will be described.

FIG. 3 illustrates an electronic device according to an embodiment of the disclosure.

Referring to FIG. 3, an electronic device 101 may include a frame 310 forming (or defining) a periphery (or a side surface) of the electronic device 101. Although not illustrated in FIG. 3, the electronic device 101 may include a rear plate that forms at least a portion of a rear surface (e.g., a surface of the electronic device 101 facing a −z direction) of the electronic device 101. The electronic device 101 may include a display that forms at least a portion of a front surface (e.g., a surface of the electronic device 101 facing a +z direction) of the electronic device 101.

For example, the frame 310 may have an approximately rectangular parallelepiped shape. The periphery of the electronic device 101 may include a first periphery 311 and a second periphery 312 parallel to a horizontal direction (e.g., an x-axis direction) of the electronic device 101 and a third periphery 313 and a fourth periphery 314 parallel to a vertical direction (e.g., a y-axis direction) of the electronic device 101. For example, the first periphery 311 may face a +y direction, and the second periphery 312 may face a −y direction. For example, the third periphery 313 may face a +x direction, and the fourth periphery 314 may face a −x direction.

According to an embodiment, the frame 310 may include a plurality of conductive portions and a plurality of non-conductive portions. The plurality of conductive portions and the plurality of non-conductive portions may form (or define) at least a portion of the periphery of the electronic device 101. The plurality of conductive portions and the plurality of non-conductive portions may form at least a portion of the periphery.

According to an embodiment, the frame 310 may include a first conductive portion 321 and/or a second conductive portion 322. For example, the first conductive portion 321 may form a portion of the first periphery 311. For example, the first conductive portion 321 may extend from a first non-conductive portion 331 of the first periphery 311 to a second non-conductive portion 332 of the first periphery 311. For example, the second conductive portion 322 may form another portion of the first periphery 311 and a portion of the third periphery 313. For example, the second conductive portion 322 may extend from the second non-conductive portion 332 to a third non-conductive portion 333 of the third periphery 313. The second conductive portion 322 may be electrically isolated from the first conductive portion 321 by the second non-conductive portion 332 disposed between the first conductive portion 321 and the second conductive portion 322. In the disclosure, among the plurality of conductive portions and the plurality of non-conductive portions forming the frame 310, the first conductive portion 321, the second conductive portion 322, the first non-conductive portion 331, the second non-conductive portion 332, and the third non-conductive portion 333 are described, but it is merely for convenience of description, and the frame 310 of the disclosure is not limited thereto. For example, in addition to the above-described conductive portions and non-conductive portions, the frame 310 may further include other conductive portions used as an antenna radiator, and may further include other non-conductive portions to electrically isolate the other conductive portions.

According to an embodiment, the first conductive portion 321 and/or the second conductive portion 322 may be configured to function as an antenna radiator. For example, the first conductive portion 321 may be configured to function as a first antenna radiator (e.g., the first antenna radiator 221 of FIG. 2), and the second conductive portion 322 may be configured to function as a second antenna radiator (e.g., the second antenna radiator 222 of FIG. 2). For example, the first conductive portion 321 may be electrically connected to wireless communication circuitry 192 through a first antenna contact 231. For example, the second conductive portion 322 may be electrically connected to the wireless communication circuitry 192 through a second antenna contact 232.

The electronic device 101 according to an embodiment may include a support 340 for supporting electronic components of the electronic device 101. For example, the support 340 may include a metal material so as to have high rigidity. The support 340 including a metal material may be configured to function as a ground of the electronic device 101. A ground point of at least one antenna radiator may be electrically connected to the support 340. For example, the first conductive portion 321 may include a first ground point electrically connected to the support 340, and the second conductive portion 322 may include a second ground point electrically connected to the support 340. A non-conductive material may be filled between the frame 310 and the support 340.

The plurality of conductive portions forming at least a portion of the periphery of the electronic device 101 may be exposed to the outside of the electronic device 101. Static electricity generated in an external environment of the electronic device 101 may flow into the electronic device 101 through the plurality of conductive portions exposed to the outside of the electronic device 101. In a case that the static electricity flowing through the plurality of conductive portions is blocked or does not flow to the ground (e.g., the support 340) of the electronic device 101, the static electricity may flow into the wireless communication circuitry 192 along an electrical path.

In a case that a high voltage of static electricity is applied to the wireless communication circuitry 192, the wireless communication circuitry 192 may be damaged, and a communication performance of the electronic device 101 may be deteriorated. The electronic device 101 according to an embodiment may include an electrostatic discharge element for blocking static electricity flowing through the plurality of conductive portions and providing the static electricity to the ground. As described above, the electrostatic discharge element may include a first electrostatic discharge element 241 electrically connected to the first conductive portion 321 corresponding to the first antenna radiator and/or a second electrostatic discharge element 242 electrically connected to the second conductive portion 322 corresponding to the second antenna radiator. The electrostatic discharge element may be electrically connected to the ground (e.g., the support 340) of the electronic device 101.

The electrostatic discharge element may be configured to block high-voltage static electricity from flowing into the wireless communication circuitry 192 and provide the static electricity to the ground. In addition, the electrostatic discharge element may be configured to choke RF signals such that the RF signals transmitted through an electrical path do not flow to the ground.

In general, a capacitor and an inductor may be used as an electrostatic discharge element. Hereinafter, a limitation of the electrostatic discharge element according to a comparative example including the capacitor and the inductor will be described.

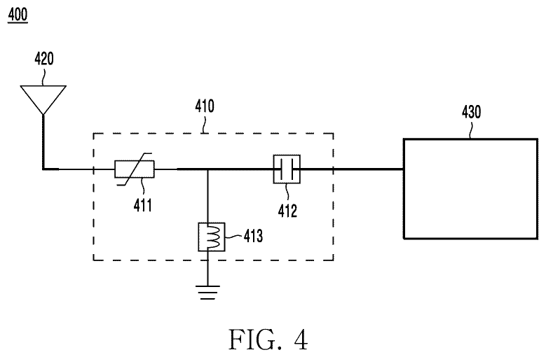

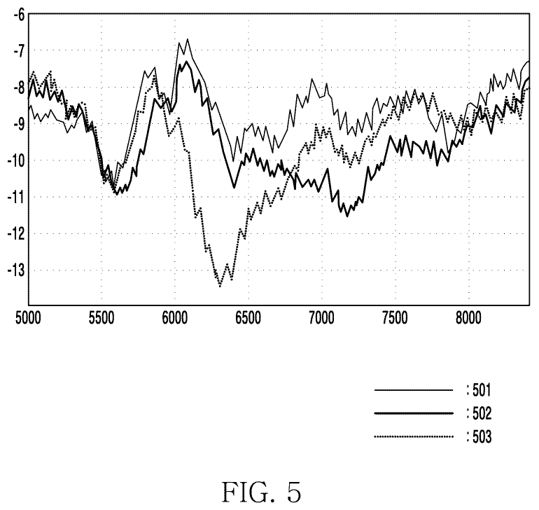

FIG. 4 is circuitry for electrostatic discharge, according to a comparative example. FIG. 5 is a graph indicating a communication performance of an electronic device according to a comparative example.

Referring to FIG. 4, circuitry 400 for the electrostatic discharge according to the comparative example may include an electrostatic discharge element 410 including at least one capacitor (e.g., a first capacitor 411 and/or a second capacitor 412) and an inductor 413. For example, the electrostatic discharge element 410 may include the first capacitor 411, the second capacitor 412, and/or the inductor 413. The first capacitor 411 may be electrically connected to an antenna radiator 420 and configured to block direct current. The second capacitor 412 may be electrically connected to wireless communication circuitry 430 and may be configured to block direct current. The inductor 413 may be electrically connected to a ground. The inductor 413 may be configured to choke alternating current such that the alternating current does not flow to the ground. For example, the direct current may pass through the inductor 413 and flow to the ground.

For example, when high-voltage static electricity flows through the antenna radiator 420, the first capacitor 411 and/or the second capacitor 412 may be configured to block the static electricity flowing through the antenna radiator 420 from flowing into the wireless communication circuitry 430. The first capacitor 411 may be disposed adjacent to the antenna radiator 420, and the second capacitor 412 may be disposed adjacent to the wireless communication circuitry 430. The first capacitor 411 adjacent to the antenna radiator 420 may primarily block the static electricity. In a case that a portion of the static electricity passes through the first capacitor 411, the portion of the static electricity may flow to the ground through the inductor 413 electrically connected to the ground. Remaining static electricity that does not flow to the ground may be blocked by the second capacitor 412. The inductor 413 may be configured to choke RF signals such that the RF signals flowing along an electrical path between the antenna radiator 420 and the wireless communication circuitry 430 do not flow to the ground.

Passive elements such as the first capacitor 411, the second capacitor 412, and the inductor 413 may be mounted on a printed circuit board. Each of the passive elements may cause a lack of a mounting space of the printed circuit board by occupying a space of the printed circuit board. Since wirings for electrically connecting the passive elements to the electrical path between the wireless communication circuitry 430 and the antenna radiator 420 are required, a structure of the printed circuit board for providing the wirings may be complicated. The wirings may cause an increase in loss of the RF signals transmitted along the electrical path, and may cause a limitation in a design for matching an antenna impedance.

In order for the inductor 413 to provide direct current caused by static electricity to the ground and choke RF signals, a high inductance of the inductor 413 may be required. The inductor 413 may include a core and copper wires wound around the core. In order to increase an inductance value of the inductor 413, turns of the copper wires may be increased. In a case that the turns of the copper wires increase, parasitic capacitance may be caused between the copper wires wound around the core. The parasitic capacitance caused by the copper wires may make an imaginary part of impedance of the inductor 413 zero at a specific frequency, and the specific frequency may be referred to as a self-resonant frequency (SRF). For signals having a frequency exceeding the self-resonant frequency, the inductor 413 may not function as the inductor 413, but may function as a bypass capacitor having a low capacitance. If, in a case that a frequency of RF signals to be transmitted and/or received through the antenna radiator 420 is included in the frequency exceeding the self-resonant frequency, the RF signals exceeding the self-resonant frequency may flow to the ground without being choked by the inductor 413.

For example, the inductor 413 for blocking RF signals may include a first inductor having an inductance of approximately 56 nH or a second inductor having an inductance of approximately 82 nH. A self-resonant frequency of the first inductor may be approximately 1.95 GHz. The first inductor may be configured to function as a bypass capacitor for RF signals having a frequency exceeding approximately 1.95 GHz. A self-resonant frequency of the second inductor may be approximately 1.44 GHz. The second inductor may be configured to function as a bypass capacitor for RF signals having a frequency exceeding approximately 1.44 GHz.

FIG. 5 is a graph 500 indicating a total radiation efficiency of an antenna according to frequency. An x-axis of the graph 500 indicates frequency (unit: MHz), and a y-axis of the graph 500 indicates a total radiation efficiency (unit: dB) of an antenna.

A first graph 501 indicates the total radiation efficiency of the antenna in a case that an inductor (e.g., the inductor 413 of FIG. 4) is omitted from the circuitry 400 of FIG. 4. A second graph 502 indicates the total radiation efficiency of the antenna in a case that a first inductor is included in the circuitry 400 of FIG. 4. A third graph 503 indicates the total radiation efficiency of the antenna in a case that a second inductor is included in the circuitry 400 of FIG. 4.

Referring to the graph 500, the first graph 501 indicates a low total radiation efficiency in a frequency range between approximately 6,000 MHz and approximately 7,000 MHz. Since the first inductor fails to choke RF signals having a frequency between approximately 6,000 MHz and approximately 7,000 MHz, the RF signals may flow to a ground, thereby deteriorating the total radiation efficiency of the antenna in the frequency range.

The second graph 502 and the third graph 503 indicate lower total radiation efficiency than the first graph 501 in a frequency range between approximately 6,000 MHz and approximately 8,000 MHz. Since the first inductor and the second inductor fail to choke RF signals having a frequency between approximately 6,000 MHz and approximately 8,000 MHz, the RF signals may flow to the ground, thereby deteriorating the total radiation efficiency of the antenna in the frequency range. For example, in a case that the antenna radiator 420 transmits and/or receives RF signals in a Wi-Fi band (e.g., approximately 6 GHz to approximately 7 GHz) or a UWB band (e.g., approximately 6 GHz to approximately 8 GHz), the inductor 413 may not choke the RF signals. As the RF signals flow to the ground, efficiency of the antenna for Wi-Fi and efficiency of the antenna for UWB may be reduced. The first inductor and the second inductor may function as a bypass capacitor in a frequency range between approximately 6,000 MHz and approximately 8,000 MHz.

The inductor 413 for choking RF signals may be required to have a high inductance. To have the high inductance, the inductor 413 may require a large number of copper wires wound around the core. In the circuitry 400 according to a comparative example, a decrease in antenna efficiency may be caused by parasitic capacitance formed by the copper wires. If, in a case that a physical size of the inductor 413 is large, problems caused by parasitic capacitance may be solved, but due to a limitation of a disposition space, the physical size of the inductor 413 may be limited. To solve the problems caused by the parasitic capacitance, in a case that the inductor 413 has a low inductance, the inductor 413 may not choke RF signals flowing to the ground.

Referring back to FIG. 4, the at least one capacitor may have a high withstand voltage characteristic to block high voltage static electricity. The at least one capacitor having the high withstand voltage characteristic may reduce a probability of being damaged by static electricity when the static electricity is applied. The at least one capacitor may have a high direct current resistance (DCR) in order to have the high withstand voltage characteristic. In a case that the at least one capacitor connected to the electrical path has the high DCR, loss of RF signals transmitted along the electrical path may increase. The total radiation efficiency of the antenna including the antenna radiator 420 may decrease due to the increase in the loss of RF signals.

The at least one capacitor of the circuitry 400 illustrated in FIG. 4 may cause a pad-to-pad discharge. For example, in a case that static electricity flowing through the antenna radiator 420 is blocked by the first capacitor 411, charges may be accumulated in the first capacitor 411. In a case that the charges cumulatively accumulated in the first capacitor 411 are discharged, a high current may be applied to the wireless communication circuitry 430 connected to the first capacitor 411. For example, the charges cumulatively accumulated in the first capacitor 411 may cause insulation breakdown of the first capacitor 411. The charges accumulated in the first capacitor 411 may be released by the insulation breakdown, and the charges may be provided to the wireless communication circuitry 430 along the electrical path. Damage to the wireless communication circuitry 430 may be caused by the charges.

As described above, the circuitry 400 illustrated in FIG. 4 may cause a problem according to the mounting space, a decrease in the antenna efficiency due to the self-resonant frequency of the inductor 413, a high DCR of the at least one capacitor, and/or a discharge accumulated in the at least one capacitor.

The electronic device (e.g., the electronic device 101 of FIG. 3) according to an embodiment may include the electrostatic discharge element for blocking static electricity flowing through the conductive portion (e.g., the first conductive portion 321 and/or the second conductive portion 322 of FIG. 3) configured to function as an antenna radiator and solving the problems. In the disclosure, the metal-insulator-metal (MIM) element may be defined as a structure in the printed circuit board with capacitor characteristics by disposing a conductive layer between dielectrics (e.g., dielectric layers). In the disclosure, the structure in the printed circuit board may be referred to as the MIM element.

As described below, the electronic device 101 may be configured to discharge static electricity using the MIM element (e.g., a first connecting member 700) and a connecting member (e.g., a second connecting member 800) and choke RF signals from flowing to the ground.

Hereinafter, the electronic device 101 including the first connecting member 700 and the second connecting member 800 configured to function as the electrostatic discharge element will be described.

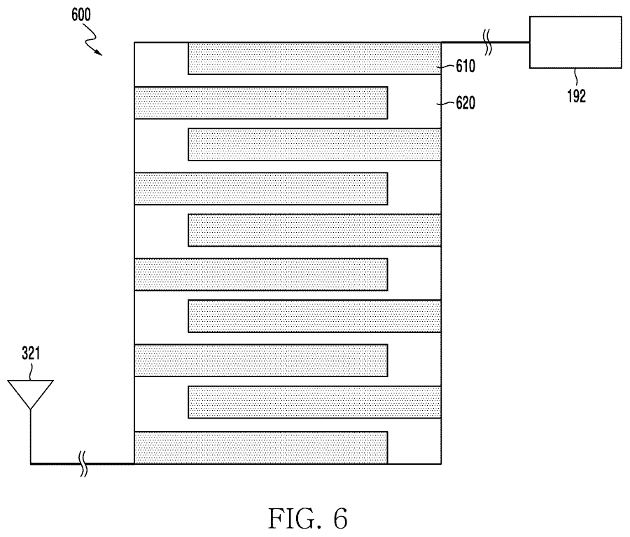

FIG. 6 is a cross-sectional view of an MIM element according to an embodiment of the disclosure.

Referring to FIG. 6, an MIM element 600 may include a metal-insulator-metal stacked structure. For example, the MIM element 600 may include a plurality of conductive layers 610 and a plurality of non-conductive layers 620 alternately stacked with the plurality of conductive layers 610. For example, the plurality of non-conductive layers 620 may be disposed between the plurality of conductive layers 610. The plurality of conductive layers 610 may include a metal material, and the plurality of non-conductive layers 620 may include an insulating material. The plurality of conductive layers 610 may not be directly connected to each other, but may be indirectly connected. For example, through coupling between the plurality of conductive layers 610, the plurality of conductive layers 610 may be electrically connected to each other.

According to an embodiment, the MIM element 600 may be electrically connected to wireless communication circuitry 192 and an antenna radiator (e.g., a first conductive portion 321), respectively. For example, the MIM element 600 may be disposed on an electrical path between the wireless communication circuitry 192 and the antenna radiator.

According to an embodiment, an electrical signal (e.g., RF signals) transmitted between the wireless communication circuitry 192 and the antenna radiator may be transmitted through the MIM element 600. For example, a transmission signal provided from the wireless communication circuitry 192 to an external electronic device may be transmitted from the wireless communication circuitry 192 to the antenna radiator through the MIM element 600. The transmission signal transmitted to the antenna radiator may be radiated to the outside of an electronic device 101 through the antenna radiator. For example, a reception signal provided from the external electronic device to the wireless communication circuitry 192 may be transmitted from the antenna radiator, through the MIM element 600, to the wireless communication circuitry 192. The reception signal received through the antenna radiator may be transmitted to the wireless communication circuitry 192 through the MIM element 600.

According to an embodiment, since the MIM element 600 includes the plurality of conductive layers 610 and the plurality of non-conductive layers 620 alternately stacked with each other, the MIM element 600 may be configured to function as a capacitor having capacitance. The MIM element 600 used as the capacitor may have a low dielectric loss due to the plurality of non-conductive layers 620 having a high dielectric constant. Since the MIM element 600 used as the capacitor may be provided as a miniaturized single element, a degree of integration of circuitry may be improved. As described below, a portion of the MIM element 600 may be configured to function as a capacitor for electrostatic discharge.

According to an embodiment, since the plurality of conductive layers 610 of the MIM element 600 may provide a portion of the electrical path between the wireless communication circuitry 192 and the antenna radiator, and at the same time, form the capacitor for the electrostatic discharge, circuitry may be formed in a narrow space. Through the plurality of conductive layers 610 of the MIM element 600, the electrical path for the RF signals transmitted between the wireless communication circuitry 192 and the antenna radiator, the capacitor for blocking static electricity, and an electrical path for providing the static electricity to the ground may be provided. Since the plurality of conductive layers 610 of the MIM element 600 may provide the electrical paths and the capacitor, a complex wiring may be omitted and a disposition space by a plurality of passive elements may be reduced.

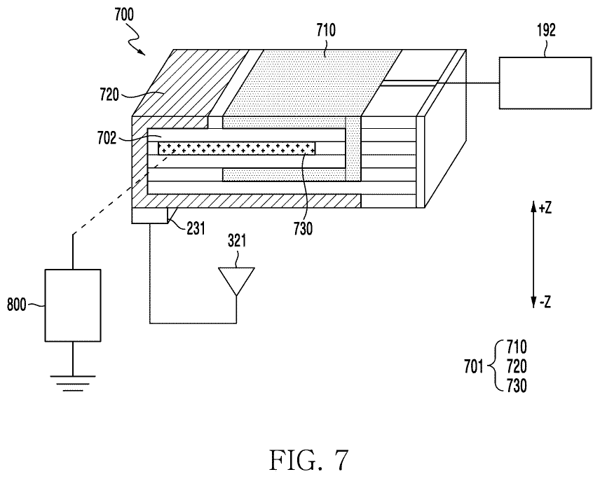

Hereinafter, a detailed structure of the MIM element 600 that blocks static electricity flowing through the antenna radiator will be described. In a description to be described later, a first connecting member (e.g., a first connecting member 700 of FIG. 7) may be referred to as the MIM element 600.

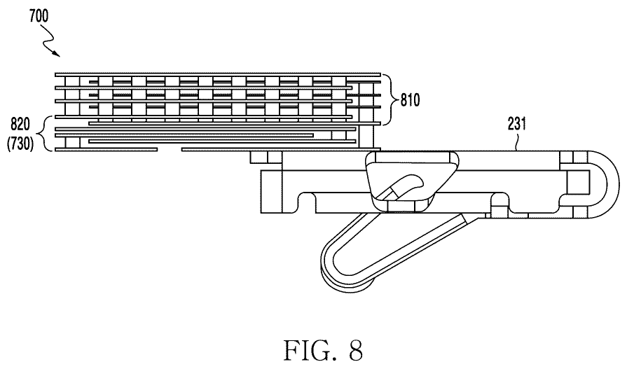

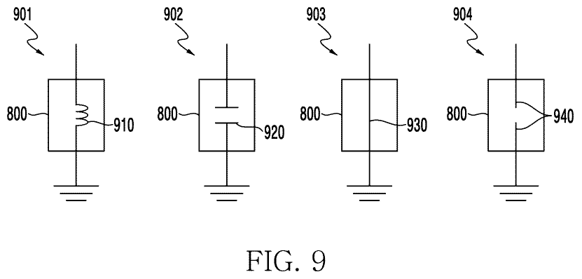

FIG. 7 schematically illustrates a first connecting member according to an embodiment of the disclosure. FIG. 8 illustrates a first connecting member in contact with an antenna contact according to an embodiment of the disclosure. FIG. 9 illustrates various examples of a second connecting member according to an embodiment of the disclosure.

A first connecting member 700 illustrated in FIG. 7 may be referred to as the MIM element (e.g., the MIM element 600 of FIG. 6) of FIG. 6. The first connecting member 700 may be electrically connected to wireless communication circuitry 192 and a conductive portion (e.g., a first conductive portion 321), respectively.

Referring to FIG. 7, the first connecting member 700 may include a plurality of conductive layers 701 and a plurality of non-conductive layers 702 alternately stacked with the plurality of conductive layers 701. At least a portion of the plurality of conductive layers 701 may be electrically connected to each other. In the following description, as an example of an antenna radiator, the first conductive portion 321 is described, and the disclosure is not limited thereto. For example, the antenna radiator may also be another conductive portion (e.g., the second conductive portion 322 of FIG. 3) other than the first conductive portion 321.

According to an embodiment, the first connecting member 700 may be electrically connected to the wireless communication circuitry 192 and the first conductive portion 321 configured to function as an antenna radiator, respectively. For example, the first connecting member 700 may be electrically connected to an electrical path between the wireless communication circuitry 192 and the first conductive portion 321. The first connecting member 700 may be electrically connected to the wireless communication circuitry 192 and the first conductive portion 321, respectively, through at least a portion of the plurality of conductive layers 701.

According to an embodiment, the first connecting member 700 may include at least one first conductive layer 710 and at least one second conductive layer 720. The at least one first conductive layer 710 may also include only a conductive layer, or may also include a plurality of two or more conductive layers 701. The at least one second conductive layer 720 may also include only a conductive layer, or may also include a plurality of two or more conductive layers 701.

According to an embodiment, the at least one first conductive layer 710 may be electrically connected to the wireless communication circuitry 192. For example, the at least one first conductive layer 710 may be connected to an electrical path electrically connected to the wireless communication circuitry 192. RF signals (e.g., transmission signals) provided from the wireless communication circuitry 192 may be provided to the first connecting member 700 through the electrical path. For example, a portion of the at least one first conductive layer 710 may be disposed on an outer surface (e.g., a front surface facing a +z direction) of the first connecting member 700.

According to an embodiment, the at least one second conductive layer 720 may be electrically connected to the first conductive portion 321 configured to function as an antenna radiator. For example, the at least one second conductive layer 720 may be electrically connected to an antenna contact 231 in contact with the first conductive portion 321. The at least one second conductive layer 720 may be electrically connected to the first conductive portion 321 through an antenna contact (e.g., the first antenna contact 231).

According to an embodiment, the at least one second conductive layer 720 may be electrically connected to the at least one first conductive layer 710. RF signals transmitted between the wireless communication circuitry 192 and the first conductive portion 321 may be transmitted through the at least one first conductive layer 710 and the at least one second conductive layer 720. The at least one second conductive layer 720 may not be directly connected to the at least one first conductive layer 710, but may be indirectly connected. For example, the at least one first conductive layer 710 and the at least one second conductive layer 720 may be electrically connected to each other by coupling (or inductive coupling) between the at least one first conductive layer 710 and the at least one second conductive layer 720.

For example, RF signals (e.g., transmission signals) transmitted to an external electronic device may be transmitted from the wireless communication circuitry 192 to the first conductive portion 321 through the at least one first conductive layer 710, the at least one second conductive layer 720, and the antenna contact 231. For example, RF signals (e.g., reception signals) received from the external electronic device may be transmitted from the first conductive portion 321 to the wireless communication circuitry 192 through the antenna contact 231, the at least one second conductive layer 720, and the at least one first conductive layer 710. The first connecting member 700 may electrically connect the wireless communication circuitry 192 and the first conductive portion 321 through a portion (e.g., the at least one first conductive layer 710 and the at least one second conductive layer 720) of the plurality of conductive layers 701. The at least one first conductive layer 710 and the at least one second conductive layer 720 may form a portion of the electrical path between the wireless communication circuitry 192 and the first conductive portion 321.

According to an embodiment, the first connecting member 700 may be configured to form a first capacitor configured to block static electricity flowing through the first conductive portion 321. For example, at least a portion of the plurality of conductive layers 701 of the first connecting member 700 and/or at least a portion of the plurality of non-conductive layers 702 of the first connecting member 700 may form the first capacitor. For example, the at least one first conductive layer 710, the at least one second conductive layer 720, and the at least a portion of the plurality of non-conductive layers 702 may form the first capacitor. For example, the at least one first conductive layer 710 and/or at least one second conductive layer 720 may correspond to an electrode of the first capacitor, and the at least a portion of the plurality of non-conductive layers 702 may correspond to a dielectric of the first capacitor. Since the first conductive portion 321 and the first connecting member 700 electrically connected to the wireless communication circuitry 192 may function as the first capacitor, the first connecting member 700 may be configured to block static electricity.

Since direct current does not pass through a capacitor and is blocked by the capacitor, static electricity flowing through the first conductive portion 321 may not pass through the first capacitor formed by the first connecting member 700 and may be blocked by the first capacitor. Since the at least one first conductive layer 710 and the at least one second conductive layer 720 are not directly connected, the at least one first conductive layer 710 and the at least one second conductive layer 720 may be electrically isolated from each other with respect to the direct current.

In a case that static electricity flows through the first conductive portion 321 exposed to the outside of an electronic device 101, the first capacitor may absorb charge based on a change in a voltage. For example, since static electricity is a direct current component, the static electricity may not pass through the first capacitor and may be blocked by the first capacitor. Since static electricity does not pass through the first capacitor, flow of a current may be blocked, with charges stored in conductive layers forming the first capacitor. As the static electricity is blocked by the first capacitor formed by the first connecting member 700, the static electricity may not be provided to the wireless communication circuitry 192. According to an embodiment, since the first connecting member 700 may be configured to block static electricity flowing through the first conductive portion 321, the wireless communication circuitry 192 may be protected from static electricity.

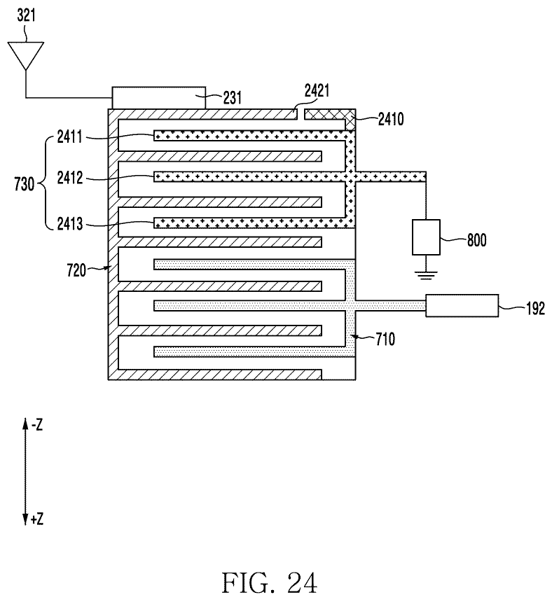

According to an embodiment, since the first connecting member 700 includes the plurality of non-conductive layers 702, it may have a high dielectric constant. Due to the high dielectric constant of the first connecting member 700, even though charges are accumulated in the first capacitor, arc discharging may be difficult to occur. Since the plurality of conductive layers 701 forming the first capacitor are at least partially surrounded by the plurality of non-conductive layers 702, arc discharging may be reduced. As described below, the first connecting member 700 may also include at least one fourth conductive layer (e.g., at least one fourth conductive layer 2410 of FIG. 24) for arc discharging.

Since alternating current may pass through the capacitor, the RF signals transmitted between the wireless communication circuitry 192 and the first conductive portion 321 may pass through the first capacitor formed by the plurality of conductive layers 701 and the plurality of non-conductive layers 702. The at least one first conductive layer 710 and the at least one second conductive layer 720 may be electrically connected to each other with respect to an RF signal. The at least one first conductive layer 710 and the at least one second conductive layer 720 may not be directly connected to each other, but may be indirectly connected to each other. For example, through coupling (e.g., inductive coupling) between the at least one first conductive layer 710 and the at least one second conductive layer 720, the at least one first conductive layer 710 and the at least one second conductive layer 720 may be electrically connected to each other. The first capacitor formed by the first connecting member 700 may be configured to function as an impedance matching element for RF signals.

According to an embodiment, the first connecting member 700 may include at least one third conductive layer 730. The at least one third conductive layer 730 may also correspond to at least one conductive layer additionally inserted into the first connecting member 700 including the plurality of conductive layers 701, or may be at least one of the plurality of conductive layers 701 of the first connecting member 700. The at least one third conductive layer 730 may form at least a portion of the first capacitor. For example, referring to FIG. 8, a plurality of conductive layers 701 of a first connecting member 700 may include eight conductive layers 810. At least one of the eight conductive layers 810 may be electrically connected to an antenna contact 231. At least one third conductive layer 730 may include four conductive layers 820 added to the first connecting member 700 including the eight conductive layers 810.

According to an embodiment, the at least one third conductive layer 730 may be electrically connected to a ground of an electronic device (e.g., the electronic device 101 of FIG. 3). As described above, the ground of the electronic device 101 may correspond to a support (e.g., the support 340 of FIG. 3). The at least one third conductive layer 730 may be electrically connected to the support 340 corresponding to the ground of the electronic device 101.

The electronic device 101 according to an embodiment may include a second connecting member 800 electrically connecting the at least one third conductive layer 730 of the first connecting member 700 to the ground of the electronic device 101. For example, the second connecting member 800 may be electrically connected to the ground and the at least one third conductive layer 730 of the first connecting member 700, respectively.

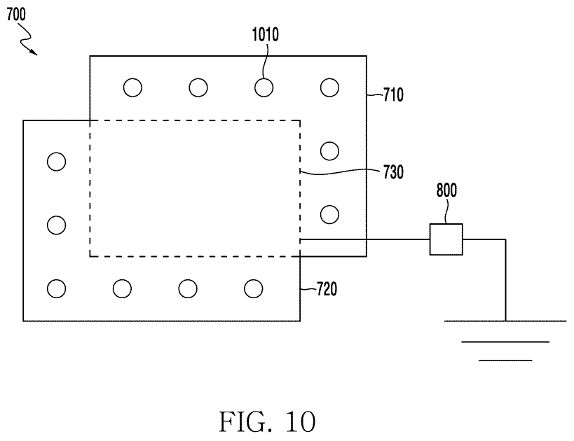

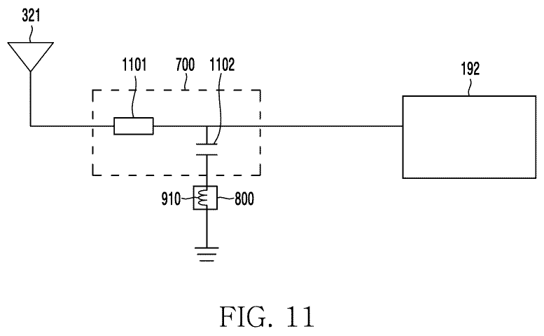

According to an embodiment, the at least one third conductive layer 730 may be used to adjust a capacitance value of the first capacitor formed by the first connecting member 700. According to an embodiment, the at least one third conductive layer 730 together with the second connecting member 800 may form a filter configured to choke RF signals such that the RF signals do not flow to the ground. For example, the capacitor and the second connecting member 800 may form at least a portion of the filter. For example, the filter may be configured to block RF signals transmitted and/or received by an antenna using the first conductive portion 321 as the antenna radiator, or to pass RF signals in a frequency band different from a frequency band of the RF signals. An example in which the at least one third conductive layer 730 adjusts the capacitance value of the first capacitor will be described later with reference to FIG. 10. An example in which the at least one third conductive layer 730 and the second connecting member 800 form a filter will be described later with reference to FIG. 11.

In FIG. 7, the at least one third conductive layer 730 including a layer is illustrated, but the at least one third conductive layer 730 of the disclosure is not limited thereto. For example, in a case that the at least one third conductive layer 730 includes two or more conductive layers, the two or more conductive layers may form a second capacitor to be described later. For example, in a case that the at least one third conductive layer 730 includes a conductive layer, the conductive layer and the at least one first conductive layer 710 (and/or the at least one second conductive layer 720) may form the second capacitor.

According to an embodiment, the at least one third conductive layer 730 may be electrically connected to the ground through the second connecting member 800. In a case that a portion of a current due to static electricity is not blocked by the first capacitor, the portion of the current may flow to the ground through the second connecting member 800. According to an embodiment, a portion of static electricity flowing through the first conductive portion 321 may be blocked by the first capacitor formed by the first connecting member 700, and a remaining portion of the static electricity may flow to the ground through the at least one third conductive layer 730 and the second connecting member 800.

Referring to FIG. 9, a second connecting member 800 electrically connected to a ground may be various. As a first example 901, the second connecting member 800 may include an inductor 910. As a second example 902, the second connecting member 800 may include a capacitor 920. As a third example 903, the second connecting member 800 may include an electrical wire 930. As a fourth example 904, the second connecting member 800 may include an electrical wire 940 electrically connected by coupling. In addition to this, the second connecting member 800 may be various.

As described with reference to FIGS. 7, 8, and 9, the first connecting member 700 may be configured to electrically connect the wireless communication circuitry 192 and the first conductive portion 321 and block static electricity. Since the first connecting member 700 may electrically connect the wireless communication circuitry 192 and the first conductive portion 321 through the plurality of conductive layers 701 and the plurality of non-conductive layers 702 included in the first connecting member 700, and may form the first capacitor for blocking static electricity, the first connecting member 700 may not require a complicated wiring. For example, since the first capacitor and the second capacitor are included in an element, the first connecting member 700 may occupy a narrower space than a plurality of passive elements (e.g., the electrostatic discharge element 410 of FIG. 4) to block static electricity. As the plurality of passive elements are replaced with the first connecting member 700, a space of a printed circuit board may be secured. According to an embodiment, since the first capacitor for blocking static electricity is formed by a plurality of layers of the first connecting member 700, it may have a relatively lower DCR than at least one capacitor (e.g., the first capacitor 411 and/or the second capacitor 412 of FIG. 4) having a high withstand voltage characteristic. Since the first capacitor formed by the first connecting member 700 has the relatively low DCR, loss of RF signals transmitted through the first connecting member 700 may be reduced. As the loss of RF signals decreases, radiation efficiency of the antenna including the first conductive portion 321 may be improved.

FIG. 10 is a plan view of a first connecting member according to an embodiment of the disclosure.

As described above, a first connecting member 700 may include a first capacitor formed by at least a portion of a plurality of conductive layers of the first connecting member 700. The at least a portion of the conductive layers forming the first capacitor may be surrounded by conductive vias 1010.

A capacitance value of a capacitor is calculated based on Equation 1 below.

$${C}_{H} = ε \times \frac{A}{D} \qquad Equation 1$$

In the Equation 1, the C_{H} is capacitance (unit: farad) of the first capacitor formed by the plurality of conductive layers. The epsilon (a) is a dielectric constant of a dielectric material positioned between the conductive layers forming the first capacitor. The dielectric constant may correspond to a dielectric constant of a plurality of non-conductive layers of the first connecting member 700. The D may correspond to a distance between the conductive layers forming the first capacitor. The distance may correspond to a thickness of at least one non-conductive layer disposed between the conductive layers forming the capacitor. The A is an area in which the conductive layers forming the first capacitor overlap each other.

Referring to Equation 1, a capacitance value of the first capacitor configured to discharge static electricity may be based on a size of the first connecting member 700.

For example, referring to the Equation 1, the capacitance value of the first capacitor configured to block static electricity may be at least partially based on the area in which the conductive layers forming the first capacitor overlap each other. For example, the capacitance value of the first capacitor may be proportional to the overlapping area. As the size of the first connecting member 700 increases, a probability that the area in which the conductive layers forming the first capacitor overlap each other increases may increase.

For example, referring to the Equation 1, the capacitance value of the first capacitor configured to block static electricity may be at least partially based on a gap between the conductive layers forming the first capacitor. For example, the capacitance value of the first capacitor may be inversely proportional to a thickness of at least one non-conductive layer disposed between the conductive layers forming the capacitor.

For example, the capacitance value of the first capacitor may be adjusted by at least one third conductive layer 730. As described above, the at least one third conductive layer 730 may be at least one of the plurality of conductive layers of the first connecting member 700. The at least one conductive layer of the plurality of conductive layers may be floated from remaining conductive layers among the plurality of conductive layers. The at least one conductive layer floated from the remaining conductive layers may be electrically connected to a ground through a second connecting member 800.

Unlike the above description, the at least one third conductive layer 730 may be at least one conductive layer additionally inserted into the first connecting member 700 to adjust the capacitance value of the first capacitor. For example, the at least one third conductive layer 730 may be additionally inserted between the plurality of conductive layers of the first connecting member 700. In this case, according to the number and a size of the at least one third conductive layer 730 to be added, the capacitance value of the first capacitor formed by the first connecting member 700 may be adjusted. For example, as the number of the at least one third conductive layer 730 to be added increases, an amount of a change in a capacitance of the first capacitor may increase. For example, as the area of the at least one third conductive layer 730 to be added increases, an amount of a change in a capacitance of the first capacitor may increase.

The capacitance value of the first capacitor formed by the first connecting member 700 may be adjusted according to various conditions such as a purpose of the electronic device 101, a function of the electronic device 101, a use environment of the electronic device 101, performance of an antenna, a frequency band of RF signals transmitted and/or received through the antenna, and the like. When the at least one third conductive layer 730 is added to the first connecting member 700, the number and/or the size of the at least one third conductive layer 730 may be determined based on the capacitance value of the first capacitor formed by the first connecting member 700. The number and the size of the at least one third conductive layer 730 may be determined such that the capacitance value of the first capacitor formed by the first connecting member 700 may be adjusted to a target capacitance value before the at least one third conductive layer 730 is added. Since the first connecting member 700 according to an embodiment may form a first capacitor having an appropriate capacitance value according to various conditions, a degree of freedom in design of the electronic device 101 may be improved, and the antenna may be optimized.

FIG. 11 is equivalent circuitry of an electronic device including a first connecting member, according to an embodiment of the disclosure.

FIG. 11 is equivalent circuitry of an electronic device 101 that includes a first connecting member 700 disposed between wireless communication circuitry 192 and a conductive portion (e.g., a first conductive portion 321) configured to function as an antenna radiator.

Although each of a first capacitor 1101 and a second capacitor 1102 is illustrated in the equivalent circuitry of FIG. 11, the first capacitor 1101 and the second capacitor 1102 may be formed by the first connecting member 700. For example, the first capacitor 1101 may be formed by at least a portion of a plurality of conductive layers of the first connecting member 700. For example, the second capacitor 1102 may be at least partially formed by at least one third conductive layer (e.g., the at least one third conductive layer 730 of FIG. 7). Since each of the first capacitor 1101 and the second capacitor 1102 is not provided as separate elements and may be formed by the first connecting member 700, the first connecting member 700 may form circuitry for electrostatic discharge in a narrow space.

According to an embodiment, the at least one third conductive layer 730 electrically connected to a second connecting member 800 may form at least a portion of the second capacitor 1102. For example, in a case that the at least one third conductive layer 730 includes only a conductive layer, the second capacitor 1102 may be formed by the at least one third conductive layer 730 and at least one conductive layer (e.g., at least one first conductive layer (e.g., the at least one first conductive layer 710 of FIG. 7) and/or at least one second conductive layer (e.g., the at least one second conductive layer 720 of FIG. 7)) of the first connecting member 700 adjacent to the at least one third conductive layer 730. For example, in a case that the at least one conductive layer includes two or more conductive layers, the second capacitor 1102 may be formed of only the at least one third conductive layer 730. Various structures of the first connecting member 700 will be described later.

According to an embodiment, the second capacitor 1102 formed by the at least one third conductive layer 730 and an inductor 910 of the second connecting member 800 may be configured to form a filter.

As described with reference to FIGS. 4 and 5, circuitry (e.g., the circuitry 400 of FIG. 4) according to a comparative example may include an inductor (e.g., the inductor 413 of FIG. 4) to choke RF signals such that the RF signals do not flow to a ground. The inductor 413 electrically connected to the ground may have a high inductance so as to choke RF signals. For example, an inductance value of the inductor 413 may be approximately 56 nH or approximately 82 nH. In order to have the high inductance, a problem due to a self-resonant frequency may be caused. Since the inductor 413 functions as a bypass capacitor at a frequency equal to or higher than the self-resonant frequency, a decrease in a total radiation efficiency of an antenna may be caused.

Referring back to FIG. 11, according to an embodiment, the second capacitor 1102 and the inductor 910 of the second connecting member 800 may form a filter such that RF signals transmitted and/or received through the conductive portion (e.g., the first conductive portion 321) configured to function as an antenna radiator do not flow to the ground. For example, the first conductive portion 321 may be configured to function as an antenna radiator for transmitting and/or receiving RF signals on a first frequency band. The wireless communication circuitry 192 may be configured to transmit and/or receive the RF signals on the first frequency band through the first conductive portion 321.

According to an embodiment, a first filter formed by the second capacitor 1102 and the inductor 910 may be configured to form a first filter having a pass band corresponding to a second frequency band different from the first frequency band. For example, the first filter may correspond to a band pass filter configured to pass RF signals on the second frequency band and choke RF signals on a frequency band different from the second frequency band.

For example, when first RF signals on the first frequency band are received through the first conductive portion 321, the first RF signals may be transmitted from the first conductive portion 321 to the wireless communication circuitry 192 through an electrical path between the first conductive portion 321 and the wireless communication circuitry 192. The first RF signals may flow to the wireless communication circuitry 192 after passing through the first capacitor 1101 formed by the first connecting member 700. Since the first filter formed by the second capacitor 1102 and the inductor 910 of the second connecting member 800 passes only second RF signals on the second frequency band, the first RF signals on the first frequency band may not pass through the first filter. Since the first filter chokes the first RF signals, the first RF signals may not flow to the ground electrically connected to the second connecting member 800, but may flow to the wireless communication circuitry 192.

For example, when the first RF signals are transmitted through the first conductive portion 321, since the first RF signals transmitted from the wireless communication circuitry 192 to the first conductive portion 321 do not pass through the first filter, they may not flow to the ground, and may be transmitted to the first conductive portion 321.

According to an embodiment, a second filter formed by the second capacitor 1102 and the inductor 910 may be configured to form a second filter having a stop band corresponding to the first frequency band. For example, the second filter may correspond to a band stop filter or a notch filter configured to choke the RF signals on the first frequency band and to pass RF signals on a frequency band different from the first frequency band.

For example, when the first RF signals on the first frequency band are received through the first conductive portion 321, the first RF signals may be transmitted from the first conductive portion 321 to the wireless communication circuitry 192 through the electrical path between the first conductive portion 321 and the wireless communication circuitry 192. The first RF signals may flow to the wireless communication circuitry 192 after passing through the first capacitor 1101 formed by the first connecting member 700. Since the second filter formed by the second capacitor 1102 and the inductor 910 of the second connecting member 800 chokes the first RF signals on the first frequency band, the first RF signals on the first frequency band may not pass through the first filter. Since the first filter chokes the first RF signals, the first RF signals may not flow to the ground electrically connected to the second connecting member 800, but may flow to the wireless communication circuitry 192.

For example, when the first RF signals are transmitted through the first conductive portion 321, since the first RF signals transmitted from the wireless communication circuitry 192 to the first conductive portion 321 do not pass through the first filter, they may not flow to the ground, and may be transmitted to the first conductive portion 321.

As described above, the second capacitor 1102 and the inductor 910 of the second connecting member 800, which are at least partially formed by the at least one third conductive layer 730, may be configured to form the first filter or the second filter. Since the first filter or the second filter may choke RF signals transmitted and/or received through the first conductive portion 321 from flowing to the ground, the at least one third conductive layer 730 and the inductor 910 may be configured to provide substantially the same function as the inductor (e.g., the inductor 413 of FIG. 4) of FIG. 4.

According to an embodiment, an inductance of the inductor 910 of the second connecting member may be lower than an inductance of the inductor (e.g., the inductor 413 of FIG. 4) of FIG. 4. For example, in a case that the inductor 413 of FIG. 4 for choking RF signals is replaced by the second capacitor 1102 of the first connecting member 700 and the inductor 910 of the second connecting member 800, the problem caused by the self-resonant frequency of the inductor 413 having a high inductance may be solved.

Hereinafter, performance of the antenna in the case of including the inductor 413 having a high inductance and performance of the antenna in the case of including the filter by the first connecting member 700 and the second connecting member 800 will be compared.

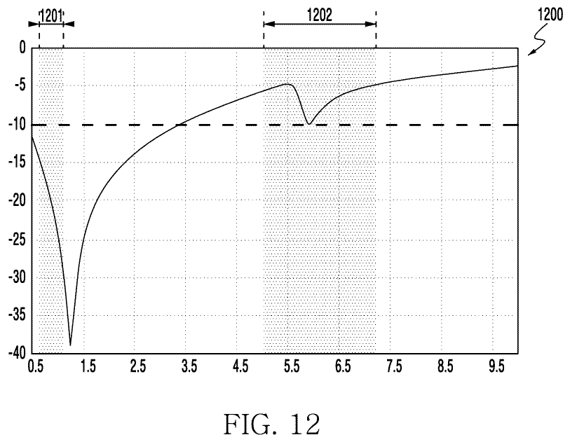

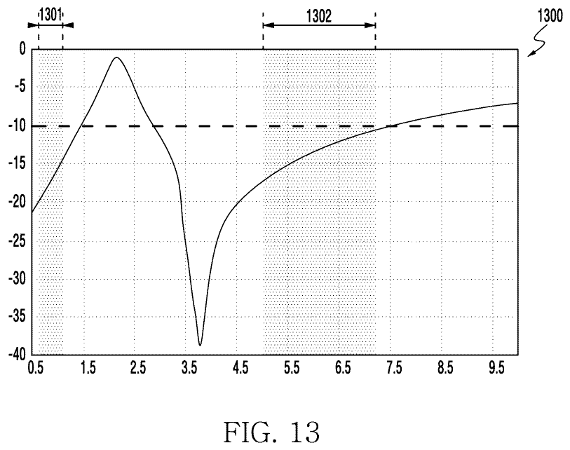

FIG. 12 is a graph indicating an S-parameter of an antenna according to frequency in the circuitry according to the comparative example of FIG. 4. FIG. 13 is a graph indicating an S-parameter of an antenna according to frequency in the circuitry of FIG. 11.

As illustrated in FIG. 4, for example, circuitry 400 according to a comparative example may include an inductor 413 having an inductance of approximately 100 nH to choke RF signals. For example, a frequency band supported by an antenna including an antenna radiator may include a low band and a Wi-Fi band. The low band may correspond to approximately 0.5 GHz to approximately 1 GHz, and the Wi-Fi band may correspond to approximately 5 GHz to approximately 7.125 GHz.

Referring to FIG. 12, an x-axis of a graph 1200 is frequency (unit: GHz), and a y-axis of the graph 1200 is an insertion loss (unit: dB). In a case that an RF signal has an insertion loss of approximately −10 dB or more, the RF signal may be choked. In other words, in order to choke RF signals by an inductor, the insertion loss of approximately −10 dB or more may be required.

Referring to the graph 1200 of FIG. 12, in a frequency band between approximately 0.5 GHz to approximately 3.5 GHz, the insertion loss may be −10 dB or more. RF signals between approximately 0.5 GHz and approximately 3.5 GHz may be choked by the inductor. In a frequency band of approximately 3.5 GHz or higher, the insertion loss may be −10 dB or less. RF signals of approximately 3.5 GHz or higher may pass through the inductor without being choked by the inductor. An inductor having the inductance of approximately 100 nH may have a high impedance for RF signals of approximately 3.5 GHz or less, but may not function as an inductor for the RF signals of approximately 3.5 GHz or higher. As described above, due to a self-resonant frequency caused by parasitic capacitance of the inductor, the inductor may be configured to function as a bypass capacitor in a frequency band equal to or higher than the self-resonant frequency.

As described above, in a case that the frequency band supported by the antenna includes a low band (e.g., a band 1201 of FIG. 12) and a Wi-Fi band (e.g., a band 1202 of FIG. 12), the inductor having the inductance of approximately 100 nH may function as an inductor for RF signals on the low band. The RF signals on the low band may be choked by the inductor. Since the inductor may not choke RF signals on the Wi-Fi band, the RF signals on the Wi-Fi band may flow to the ground. Since the RF signals on the Wi-Fi band are radiated through the antenna radiator (e.g., the antenna radiator 420 of FIG. 4) or may not be transmitted to wireless communication circuitry (e.g., the wireless communication circuitry 430 of FIG. 4) and flow to the ground, performance of the antenna for Wi-Fi may deteriorate.

As illustrated in FIG. 11, for example, an electronic device (e.g., the electronic device 101 of FIG. 3) according to an embodiment may include a filter formed by a second capacitor (e.g., the second capacitor 1102 of FIG. 11) and an inductor (e.g., the inductor 910 of FIG. 12) to choke RF signals. For example, the second capacitor may be at least partially formed by at least one third conductive layer (e.g., the at least one third conductive layer 730 of FIG. 7) of a first connecting member (e.g., the first connecting member 700 of FIG. 11). For example, the inductor may correspond to a second connecting member (e.g., the second connecting member 800 of FIG. 11). The second capacitor may have a capacitance of approximately 0.25 pF, and the inductor may have an inductance of approximately 15 nH. For example, a frequency band supported by an antenna including a first conductive portion 321 may include a low band and a Wi-Fi band. The low band may correspond to approximately 0.5 GHz to approximately 1 GHz, and the Wi-Fi band may correspond to approximately 5 GHz to approximately 7.125 GHz.

Referring to FIG. 13, an x-axis of a graph 1300 is frequency (unit: GHz), and a y-axis of the graph 1300 is an S-parameter (unit: dB). In a case that an RF signal has an insertion loss of approximately −10 dB or more, the RF signal may be choked. In other words, in order to choke RF signals by a filter, the insertion loss of approximately −10 dB or more may be required.

Referring to the graph 1300 of FIG. 13, in each of a frequency band between approximately 0.5 GHz to approximately 1 GHz corresponding to a low band (e.g., a band 1301 of FIG. 13) and a frequency band between approximately 5 GHz to approximately 7.125 GHz corresponding to a Wi-Fi band (e.g., a band 1302 of FIG. 13), an insertion loss may be approximately −10 dB or more. RF signals on the low band and RF signals on the Wi-Fi band may be choked by a filter. Since the RF signals on the low band and the RF signals on the Wi-Fi band may be choked by the filter, the RF signals on the low band and the RF signals on the Wi-Fi band may not flow to a ground. Since the RF signals on the low band and the RF signals on the Wi-Fi band do not flow to the ground, performance of an antenna including a first conductive portion (e.g., the first conductive portion 321 of FIG. 11) may be maintained.

As described above, an inductor (e.g., the inductor 910 of FIG. 11) of a second connecting member 800 has an inductance of approximately 15 nH, and an inductor (e.g., the inductor 413 of FIG. 4) according to a comparative example has an inductance of approximately 100 nH. Referring to FIG. 11, since an inductor 910 of the second connecting member 800 has a low inductance, a problem according to a self-resonant frequency caused by parasitic capacitance may be solved. Since the filter formed by the inductor of the second connecting member 800 and the second capacitor may choke (or filter) RF signals on a designated frequency band, performance of the antenna for the RF signals may be maintained.

According to an embodiment, a capacitance value of the second capacitor and an inductance value of the inductor may be based on a frequency band supported by the antenna including the first conductive portion 321. For example, since a stop band or a pass band of the filter is determined by the capacitance value and the inductance value, the capacitance value and the inductance value may be based on a frequency band of RF signals transmitted and/or received through the antenna including the first conductive portion 321.

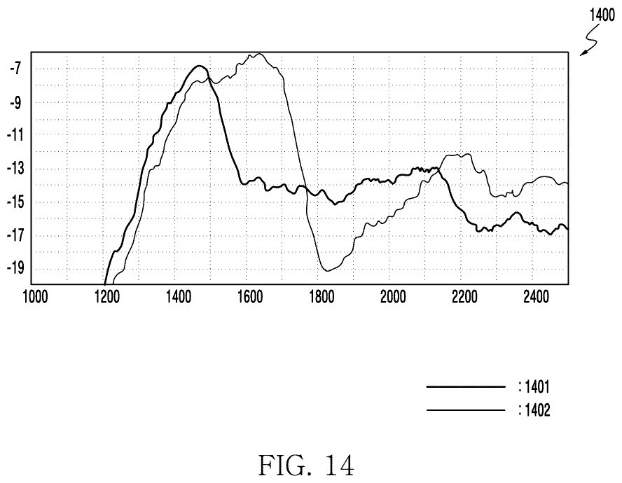

FIG. 14 is a graph indicating a total radiation efficiency of a second antenna including a second antenna radiator adjacent to a first antenna radiator.

Referring back to FIG. 3, as described above, a frame 310 may include a first conductive portion 321 and a second conductive portion 322. The first conductive portion 321 may be configured to function as an antenna radiator for transmitting and/or receiving RF signals on a first frequency band. The second conductive portion 322 may be configured to function as an antenna radiator for transmitting and/or receiving RF signals on a second frequency band different from the first frequency band. For example, a first antenna including a first antenna radiator may be configured to transmit and/or receive RF signals on a low band and/or a Wi-Fi band. For example, a second antenna including a second antenna radiator may be configured to transmit and/or receive RF signals on a GPS band (e.g., approximately 1,500 MHz to approximately 1,600 MHz).

The circuitry illustrated in FIG. 11 may be referred to as circuitry to be electrically connected to the first antenna radiator. As described above, an electronic device 101 may include a filter formed by a second capacitor (e.g., the second capacitor 1102 of FIG. 11) and an inductor (e.g., the inductor 910 of FIG. 11). The filter may be configured to choke first RF signals transmitted and/or received through the first antenna radiator. In a case that the electronic device 101 includes the filter electrically connected to the first antenna radiator, isolation between the first antenna and the second antenna adjacent to each other may be improved.

A graph 1400 of FIG. 14 indicates a total radiation efficiency according to frequency of the second antenna. An x-axis of the graph 1400 of FIG. 14 indicates frequency (unit: MHz), and a y-axis of the graph 1400 indicates a total radiation efficiency (unit: dB) of an antenna.

A first graph 1401 of FIG. 14 indicates a total radiation efficiency of the second antenna in a case that the filter electrically connected to the first antenna radiator is not included. For example, the case that the filter is not included may correspond to a case that the second connecting member 800 does not include the inductor, but includes a capacitor (e.g., the capacitor 920 of FIG. 9), an electrical wire (e.g., the electrical wire 930 of FIG. 9), or an electrical wire (e.g., the electrical wire 940 of FIG. 9) electrically connected by a coupling.

A second graph 1402 of FIG. 14 indicates a total radiation efficiency of the second antenna in a case that the filter electrically connected to the first antenna radiator is included. For example, the case that the filter is included may correspond to a case that the second connecting member (e.g., the second connecting member 800 of FIG. 11) includes an inductor (e.g., the inductor 910 of FIG. 11).

Comparing the first graph 1401 and the second graph 1402, the second graph 1402 indicates a higher radiation efficiency than the first graph 1401 in a frequency band between approximately 1,500 MHz to approximately 1,600 MHz. By improving the isolation between the first antenna and the second antenna by the filter electrically connected to the first antenna radiator, the efficiency of the second antenna may be improved. For example, the filter may be a notch filter having a stop band in a second frequency band different from the first frequency band. In a case that the notch filter is electrically connected to the first antenna radiator, since it is difficult for RF signals on the second frequency band to be induced to the first antenna, the total radiation efficiency of the second antenna with respect to the RF signals may be improved. According to an embodiment, the first connecting member 700 and the second connecting member 800 may discharge static electricity and improve isolation from an adjacent antenna. In a case of the electronic device 101 having a small size, a plurality of antennas may be adjacent to each other. In a case that a plurality of antennas are adjacent to each other, isolation between the antennas may be required. Since the electronic device 101 may improve isolation between adjacent antennas through the filter formed by the first connecting member 700 and the second connecting member 800 for electrostatic discharge, a degree of freedom in design of the electronic device 101 may be improved.

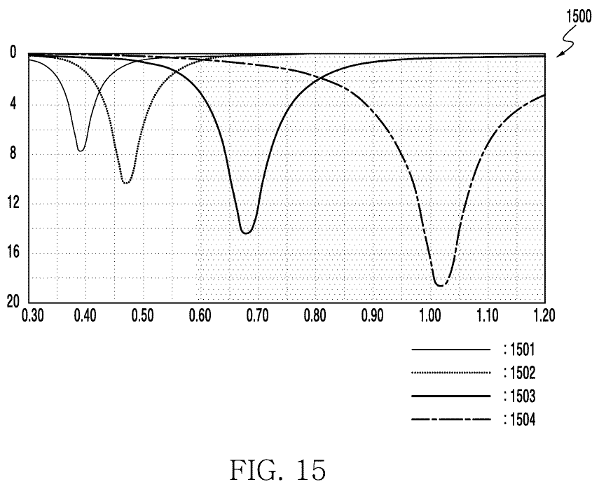

FIG. 15 is a graph indicating an S-parameter of an antenna according to an inductance value of an inductor of a second connecting member.

In a case that a second capacitor (e.g., the second capacitor 1102 of FIG. 11) formed by a first connecting member (e.g., the first connecting member 700 of FIG. 11) has a capacitance of approximately 2.0 pF, a graph 1500 of FIG. 15 indicates an insertion loss of an antenna according to a change in an inductance value of an inductor (e.g., the inductor 910 of FIG. 11) of a second connecting member (e.g., the second connecting member 800 of FIG. 11). The antenna may be referred to as an antenna including an antenna radiator electrically connected to the filter. An x-axis of the graph 1500 indicates frequency (unit: GHz), and a y-axis of the graph 1500 indicates an insertion loss (unit: dB) of an antenna. The frequency at which a dip of the graph 1500 is generated may correspond to a stop band of a filter formed by the second capacitor and the inductor. The antenna is assumed to be an antenna for transmitting and/or receiving RF signals on a low band (e.g., approximately 0.5 GHz to approximately 1 GHz).

Referring to FIG. 15, a first graph 1501 indicates an insertion loss of the antenna electrically connected to the filter in a case that an inductance of an inductor of a second connecting member 800 is approximately 82 nH. A second graph 1502 indicates an insertion loss of the antenna electrically connected to the filter in a case that the inductance of the inductor of the second connecting member 800 is approximately 56 nH. A third graph 1503 indicates an insertion loss of the antenna electrically connected to the filter in a case that the inductance of the inductor of the second connecting member 800 is approximately 27 nH. A fourth graph 1504 indicates an insertion loss of the antenna electrically connected to the filter in a case that the inductance of the inductor of the second connecting member 800 is approximately 12 nH.

Referring to the first graph 1501, in a case that the inductance of the inductor is approximately 82 nH, a stop band of the filter may correspond to a frequency band around approximately 0.35 GHz to approximately 0.40 GHz. Referring to the second graph 1502, in a case that the inductance of the inductor is approximately 56 nH, a stop band of the filter may correspond to a frequency band around approximately 0.45 GHz to approximately 0.50 GHz. Referring to the third graph 1503, in a case that the inductance of the inductor is approximately 27 nH, a stop band of the filter may correspond to a frequency band around approximately 0.65 GHz to approximately 0.70 GHz. Referring to the fourth graph 1504, in a case that the inductance of the inductor is approximately 12 nH, a stop band of the filter may correspond to a frequency band around approximately 1.00 GHz to approximately 1.05 GHz.

Referring to FIG. 15, a stop band of a filter may be adjusted according to an inductance value of an inductor. As described above, the filter may be configured to choke RF signals such that the RF signals transmitted and/or received through the antenna do not flow to a ground. The filter may correspond to a notch filter (or a band stop filter) having a stop band corresponding to a frequency band transmitted and/or received through the antenna or a band pass filter having a pass band corresponding to another frequency band different from the frequency band. In order to appropriately set the stop band of the filter or the pass band of the filter, a capacitance value of the second capacitor or an inductance value of the inductor of the second connecting member 800 may be appropriately selected. For example, the capacitance value of the second capacitor may be determined based on a size of at least one third conductive layer 730.

As described above, according to a comparative example, since an inductor (e.g., the inductor 413 of FIG. 4) for electrostatic discharge has an inductance of approximately 82 nH or approximately 56 nH, it has a relatively high inductance. To have the relatively high inductance, the inductor may require a large number of copper wires wound around a core. Due to the copper wires, a problem associated with parasitic capacitance and a self-resonant frequency is caused. According to an embodiment, since the inductor may have an inductance of approximately 12 nH to approximately 27 nH in a case that a filter is formed by a second capacitor 1102 at least partially formed by the at least one third conductive layer 730 of a first connecting member 700 and the inductor 910 of the second connecting member 800, an inductance value of the inductor 910 may be reduced. As the inductance value decreases, turns of the copper wires may decrease, and thus a problem according to a self-resonant frequency may be solved.

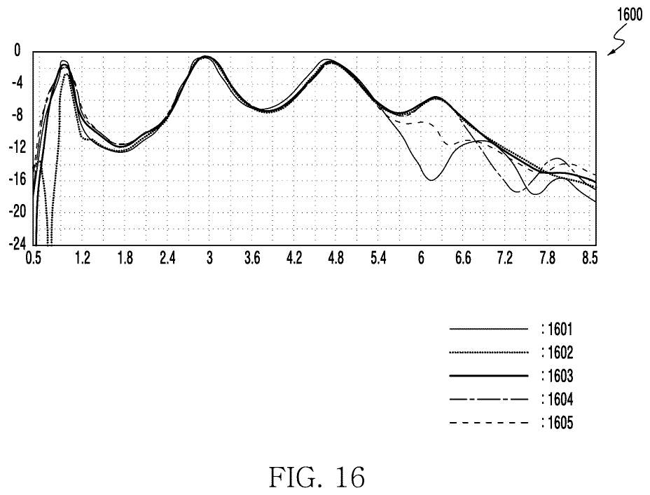

FIG. 16 is a graph indicating a total radiation efficiency of an antenna according to an inductance value of an inductor of a second connecting member.

In a case that a second capacitor formed by a first connecting member (e.g., the first connecting member 700 of FIG. 11) has a capacitance of approximately 3.9 pF, a graph 1600 of FIG. 16 indicates an insertion loss of an antenna according to a change in an inductance value of an inductor (e.g., the inductor 910 of FIG. 11) of a second connecting member (e.g., the second connecting member 800 of FIG. 11). The antenna may be referred to as an antenna including an antenna radiator electrically connected to the filter. An x-axis of the graph 1600 indicates frequency (unit: GHz), and a y-axis of the graph 1600 indicates a total radiation efficiency (unit: dB) of an antenna.

Referring to FIG. 16, a first graph 1601 indicates a total radiation efficiency of the antenna in a case that an inductor having an inductance of approximately 82 nH is electrically connected to the antenna radiator. For example, the inductor may be referred to as an inductor (e.g., the inductor 413 of FIG. 4) of circuitry (e.g., the circuitry 400 of FIG. 4) illustrated in FIG. 4 rather than the inductor 910 of the second connecting member 800. A second graph 1602 indicates a total radiation efficiency of the antenna electrically connected to the filter in a case that the inductance of the inductor 910 of the second connecting member 800 is approximately 12 nH. A third graph 1603 indicates a total radiation efficiency of the antenna electrically connected to the filter in a case that the inductance of the inductor 910 of the second connecting member 800 is approximately 27 nH. A fourth graph 1604 indicates a total radiation efficiency of the antenna electrically connected to the filter in a case that the inductance of the inductor 910 of the second connecting member 800 is approximately 56 nH. A fifth graph 1605 indicates a total radiation efficiency of the antenna electrically connected to the filter in a case that the inductance of the inductor 910 of the second connecting member 800 is approximately 82 nH.

Referring to the first graph 1601, the antenna has a low total radiation efficiency in a frequency band between approximately 5.7 GHz and approximately 6.3 GHz. As described with reference to FIG. 4, due to the parasitic capacitance of the inductor 413, the inductor 413 may function as a bypass capacitor. RF signals on the frequency band between approximately 5.7 GHz and approximately 6.3 GHz may pass through the inductor without being choked by the inductor 413. Since the RF signals may flow to a ground, the total radiation efficiency of the antenna may be lowered in the frequency band between approximately 5.7 GHz and approximately 6.3 GHz.

Referring to the second graph 1602, the antenna has a low total radiation efficiency in a low band (e.g., approximately 0.5 GHz to approximately 1.0 GHz). In a case that a capacitance of a second capacitor 1102 is approximately 3.9 pF and an inductance of the inductor 910 is approximately 12 nH, the filter formed by the second capacitor 1102 of a first connecting member 700 and the inductor 910 of the second connecting member 800 may have a pass band corresponding to the low band. As indicated in the second graph 1602, since RF signals on the low band may pass through the filter, performance of the antenna for the low band may be deteriorated. If, in a case that the antenna transmits and/or receives RF signals on the low band, the filter may not be appropriate.

Referring to the fifth graph 1605, the antenna has a low total radiation efficiency in a frequency band between approximately 5.7 GHz and approximately 6.3 GHz. In a case that the inductance of the inductor 910 of the second connecting member 800 is approximately 82 nH, due to parasitic capacitance of the inductor 910, the inductor 910 may function as a bypass capacitor.

The third graph 1603 and the fourth graph 1604 indicate a relatively high total radiation efficiency. In a case that the antenna transmits and/or receives RF signals on a low band and a Wi-Fi band (e.g., approximately 6 GHz to approximately 7 GHz), and the capacitance of the second capacitor 1102 is approximately 3.9 pF, the inductor 910 of the second connecting member 800 having an inductance of approximately 27 nH or approximately 56 nH may be appropriate to secure communication performance of an electronic device 101.

As described with reference to FIGS. 15 and 16, the second capacitor (e.g., the second capacitor 1102 of FIG. 11) at least partially formed by the at least one third conductive layer (e.g., the at least one third conductive layer 730 of FIG. 7) of the first connecting member (e.g., the first connecting member 700 of FIG. 11) and the inductor (e.g., the inductor 910 of FIG. 11) of the second connecting member (e.g., the second connecting member 800 of FIG. 11) may be appropriately selected to solve problems caused by parasitic capacitance. The filter formed by the second capacitor 1102 and the inductor 910 may be configured to choke RF signals such that the RF signals transmitted and/or received through the antenna (e.g., the antenna using the first conductive portion 321 of FIG. 3 as an antenna radiator) do not flow to the ground. Since the inductor of the filter has a relatively low inductance value, problems caused by parasitic capacitance may be solved. The first connecting member 700 and the second connecting member 800 may block static electricity flowing through the antenna radiator, thereby reducing deterioration of the communication performance of the electronic device 101.

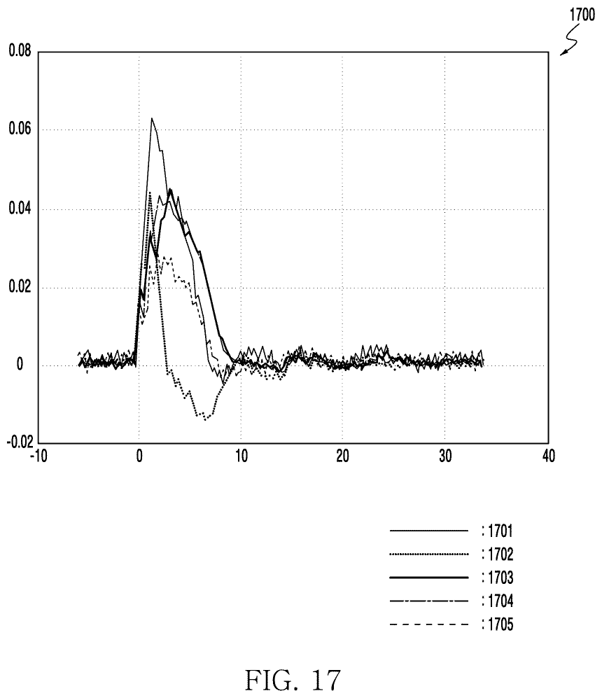

FIG. 17 is a graph indicating a transmission line pulse (TLP) test result.

When a high voltage is instantaneously applied to circuitry due to flowing of static electricity, as an amount of current is reduced, the static electricity may be discharged. An electrostatic discharge performance may be checked through a transmission line pulse (TLP) test. In the TLP test, when static electricity is applied to circuitry, an amount of current instantaneously induced in the circuitry is measured. As an electrostatic discharge performance of the circuitry is high, a maximum value of the current measured in the TLP test is small.

A graph 1700 of FIG. 17 indicates the TLP test result. An x-axis of the graph 1700 indicates a time (unit: nano second), and a y-axis of the graph 1700 indicates a current (units: ampere).

A first graph 1701 of FIG. 17 indicates a TLP test result of circuitry that does not include an electrostatic discharge element. The circuitry that does not include the electrostatic discharge element may be referred to as circuitry to which a capacitor having a capacitance of approximately 20 pF is connected between an antenna radiator and wireless communication circuitry.

A second graph 1702 of FIG. 17 indicates a TLP test result of the circuitry of FIG. 4. The circuitry of FIG. 4 may include a first capacitor (e.g., the first capacitor 411 of FIG. 4), a second capacitor (e.g., the second capacitor 412 of FIG. 4), and an inductor (e.g., the inductor 413 of FIG. 4) of FIG, as an electrostatic discharge element. 4. For example, each of the first capacitor and the second capacitor may have a capacitance of approximately 20 pF, and the inductor may have an inductance of approximately 82 nH.

Each of a third graph 1703, a fourth graph 1704, and a fifth graph 1705 of FIG. 17 indicates a TLP test result of the circuitry of FIG. 11. The circuitry of FIG. 11 may include a first capacitor (e.g., the first capacitor 1101 of FIG. 11) and a second capacitor (e.g., the second capacitor 1102 of FIG. 11) formed by a first connecting member (e.g., the first connecting member 700 of FIG. 11), and an inductor (e.g., the inductor 910 of FIG. 11) of a second connecting member (e.g., the second connecting member 800 of FIG. 11). The third graph 1703 indicates a TLP test result of circuitry including a first capacitor having a capacitance of approximately 20 pF, a second capacitor having a capacitance of approximately 20 pF, and an inductor having an inductance of approximately 18 nH. The fourth graph 1704 indicates a TLP test result of circuitry including a first capacitor having a capacitance of approximately 20 pF, a second capacitor having a capacitance of approximately 20 pF, and an inductor having an inductance of approximately 9 nH. The fifth graph 1705 indicates a TLP test result of circuitry including a first capacitor having a capacitance of approximately 10 pF, a second capacitor having a capacitance of approximately 20 pF, and an inductor having an inductance of approximately 9 nH.

The first graph 1701 of FIG. 17 indicates a maximum current of approximately 0.06 A. In the circuitry that does not include an electrostatic discharge element, since it is difficult to discharge static electricity flowing through the antenna radiator, a maximum current due to the static electricity may be high. In the circuitry that does not include an electrostatic discharge element, the wireless communication circuitry may be easily damaged by the high current.

All of the second graph 1702, the third graph 1703, and the fourth graph 1704 of FIG. 17 indicate a maximum current of approximately 0.04 A. An electronic device (e.g., the electronic device 101 of FIG. 3) according to an embodiment including a first connecting member 700 and a second connecting member 800 instead of the electrostatic discharge element (e.g., the first capacitor 411, the second capacitor 412, and the inductor 413 of FIG. 4) of FIG. 4 may provide an electrostatic discharge performance similar to that of including the electrostatic discharge element. Since the electronic device 101 according to an embodiment has an inductance (e.g., approximately 18 nH or approximately 9 nH) lower than the inductance (e.g., approximately 82 nH) of the inductor of FIG. 4, problems caused by the parasitic capacitance of the inductor may not be caused, and an electrostatic discharge performance similar to that of the circuitry of FIG. 4 may be provided.

The fifth graph 1705 of FIG. 17 indicates a maximum current of approximately 0.026 A. As a capacitance value of the first capacitor and an inductance value of an inductor of the second connecting member 800 are adjusted, an electrostatic discharge performance may be improved. Since the capacitance value of the first capacitor and the inductance value of the inductor of the second connecting member 800 may be adjusted according to various conditions, such as a purpose of the electronic device 101, a function of the electronic device 101, a use environment of the electronic device 101, performance of an antenna, a frequency band of RF signals transmitted and/or received through the antenna, and the like, a degree of freedom in design of the electronic device 101 may be improved.

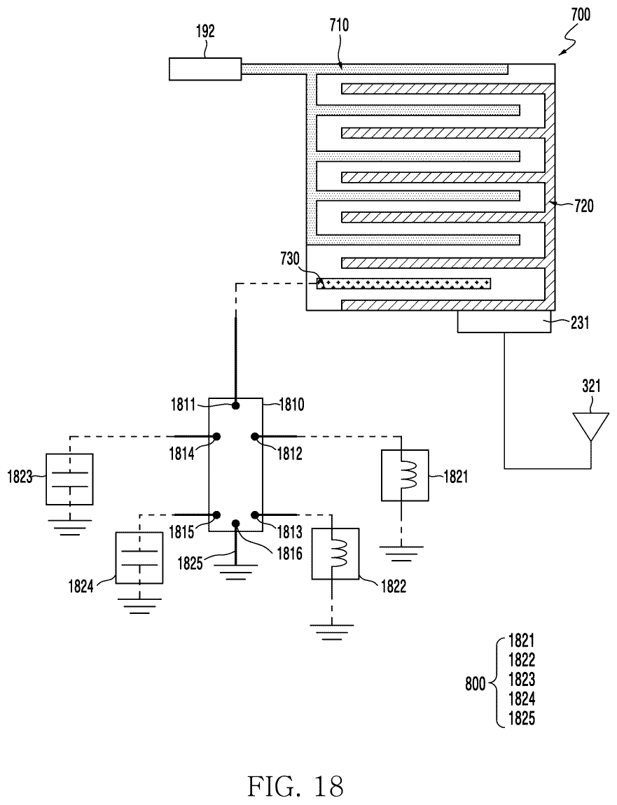

FIG. 18 illustrates an electronic device including a switch circuit according to an embodiment of the disclosure.

Referring to FIG. 18, a second connecting member 800 may include a plurality of sub connecting members. For example, the plurality of sub connecting members may include a passive element including a capacitor and/or an inductor, which are electrically connected to a ground. For example, the plurality of sub connecting members may include an electrical wire 1825 electrically connected to the ground. As illustrated in FIG. 18, the plurality of sub connecting members may include a first inductor 1821 having a first inductance value, a second inductor 1822 having a second inductance value, a first capacitor 1823 having a first capacitance value, a second capacitor 1824 having a second capacitance value, and/or the electrical wire 1825.

An electronic device (e.g., the electronic device 101 of FIG. 3) according to an embodiment may include a switch circuit 1810. The switch circuit 1810 may be configured to electrically connect at least one third conductive layer 730 at least partially forming the above-described second capacitor 1824 to any one sub connecting member of the plurality of sub connecting members of the second connecting member 800.

For example, the switch circuit 1810 may include a first terminal 1811 electrically connected to the at least one third conductive layer 730. The switch circuit 1810 may include a second terminal 1812 electrically connected to the first inductor 1821, a third terminal 1813 electrically connected to the second inductor 1822, a fourth terminal 1814 electrically connected to the first capacitor 1823, a fifth terminal 1815 electrically connected to the second capacitor 1824, and/or a sixth terminal 1816 electrically connected to the electrical wire 1825.

According to an embodiment, the at least one third conductive layer 730 may be electrically connected to one sub connecting member of the plurality of sub connecting members through the switch circuit 1810. For example, when the first terminal 1811 and the second terminal 1812 are electrically connected, the at least one third conductive layer 730 may be electrically connected to the first inductor 1821. When the first terminal 1811 and the third terminal 1813 are electrically connected, the at least one third conductive layer 730 may be electrically connected to the second inductor 1822. When the first terminal 1811 and the fourth terminal 1814 are electrically connected, the at least one third conductive layer 730 may be electrically connected to the first capacitor 1823. When the first terminal 1811 and the fifth terminal 1815 are electrically connected, the at least one third conductive layer 730 may be electrically connected to the second capacitor 1824. When the first terminal 1811 and the sixth terminal 1816 are electrically connected, the at least one third conductive layer 730 may be electrically connected to the electrical wire 1825. The switch circuit 1810 and the plurality of sub connecting members illustrated in FIG. 18 are merely an example, and the disclosure is not limited thereto.

According to an embodiment, the switch circuit 1810 may be configured to electrically connect the at least one third conductive layer 730 to one of the plurality of sub connecting members so as to effectively discharge static electricity flowing through an antenna radiator (e.g., the first conductive portion 321 of FIG. 3).

For example, the switch circuit 1810 may be controlled by at least one processor (e.g., the processor 120 of FIG. 1). For example, in order to adjust a capacitance value of the first capacitor 1823 formed by a first connecting member 700, the at least one processor 120 may be configured to control the switch circuit 1810 such that the at least one third conductive layer 730 and the first capacitor 1823 (or the second capacitor 1824) are electrically connected.

For example, the at least one processor 120 may be configured to control the switch circuit 1810 to adjust a characteristic of the above-described filter. As described above, the second capacitor 1824 formed by the at least one third conductive layer 730 and an inductor of the second connecting member 800 may form a filter. The filter may have a characteristic based on a frequency band (e.g., a first frequency band) supported by an antenna including a first conductive portion 321. For example, in a case that the filter is a notch filter (or a band stop filter), the filter may have a stop band corresponding to the first frequency band. For example, in a case that the filter is a band pass filter, the filter may have a pass band corresponding to a second frequency band different from the first frequency band.

Since the characteristic of the filter may be changed according to an inductance value of the inductor of the second connecting member 800 forming the filter, the at least one processor 120 may be configured to control the switch circuit 1810 based on the first frequency band. For example, the at least one processor 120 may be configured to control the switch circuit 1810 to electrically connect the at least one third conductive layer 730 to the first inductor 1821 or the second inductor 1822 such that the notch filter having the stop band corresponding to the first frequency band may be formed. For example, the at least one processor 120 may be configured to control the switch circuit 1810 to electrically connect the at least one third conductive layer 730 to the first inductor 1821 or the second inductor 1822 such that the band pass filter having the pass band corresponding to the second frequency band different from the first frequency band may be formed.

The first connecting member 700 according to an embodiment may form a first capacitor that blocks direct current and a second capacitor that forms a portion of the filter. As described above, the first connecting member 700 may correspond to an MIM element. A structure of the first connecting member 700 may vary.

Hereinafter, various examples of the first connecting member 700 electrically connected to wireless communication circuitry 192 and the first conductive portion 321, respectively, will be described.

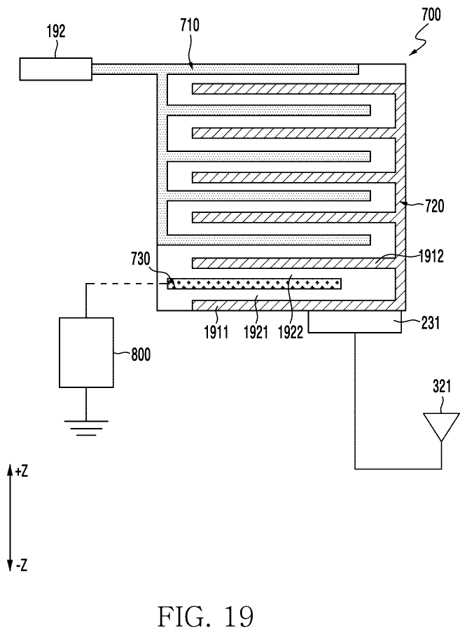

FIGS. 19, 20, 21, 22, and 23 illustrate various examples of a first connecting member according to various embodiments of the disclosure.

A first connecting member 700 illustrated in FIGS. 19 to 23 may include at least one first conductive layer 710 electrically connected to wireless communication circuitry 192, at least one second conductive layer 720 electrically connected to a conductive portion (e.g., a first conductive portion 321) configured to function as an antenna radiator, and at least one third conductive layer 730 at least partially forming a second capacitor. The at least one third conductive layer 730 may be electrically connected to a ground of an electronic device 101 through a second connecting member 800. RF signals transmitted between the wireless communication circuitry 192 and the first conductive portion 321 may be transmitted through the first connecting member 700.

According to an embodiment, the first connecting member 700 may at least partially form a first capacitor configured to block static electricity. For example, a plurality of conductive layers (e.g., the at least one first conductive layer 710, the at least one second conductive layer 720, and/or the at least one third conductive layer 730) of the first connecting member 700 may not be directly connected to each other, but may be indirectly connected to each other. Since the plurality of conductive layers are indirectly connected to each other, direct current may not be transmitted through the plurality of conductive layers, and thus static electricity may be blocked by the first connecting member 700.

Referring to FIG. 19, at least one third conductive layer 730 may be closer to an antenna contact 231 among wireless communication circuitry 192 and the antenna contact 231.

For example, the antenna contact 231 may be disposed on a rear surface (e.g., a surface of a first connecting member 700 facing a −z direction) of the first connecting member 700. At least one second conductive layer 720 may include a first sub conductive layer 1911 disposed on the rear surface of the first connecting member 700 and a second sub conductive layer 1912 positioned above the first sub conductive layer 1911 (e.g., in +z direction). The antenna contact 231 may be electrically connected to the first sub conductive layer 1911. The antenna contact 231 may be electrically connected to the first conductive portion 321 configured to function as an antenna radiator.

For example, the at least one third conductive layer 730 may be positioned above the first sub conductive layer 1911. The at least one third conductive layer 730 may be positioned below the second sub conductive layer 1912 (e.g., in −z direction). A first non-conductive layer 1921 may be disposed between the first sub conductive layer 1911 and the at least one third conductive layer 730. A second non-conductive layer 1922 may be disposed between the second sub conductive layer 1912 and the at least one third conductive layer 730. The first non-conductive layer 1921 and the second non-conductive layer 1922 may be connected to each other or may also be separated from each other. The at least one third conductive layer 730 may be electrically connected to a ground through a second connecting member 800.

For example, the second connecting member 800 may include an inductor. The at least one third conductive layer 730 may at least partially form a second capacitor. The inductor and the second capacitor may form a filter.

For example, in a case that the at least one third conductive layer 730 includes a plurality of conductive layers, the at least one third conductive layer 730 may form the second capacitor. For example, in a case that the at least one third conductive layer 730 includes only a conductive layer, the at least one third conductive layer 730 may form the second capacitor together with at least a portion of a plurality of conductive layers of the first connecting member 700. For example, the second capacitor may be formed by the at least one third conductive layer 730 and a first sub conductive layer 1911 and/or a second sub conductive layer 1912 adjacent to the at least one third conductive layer 730.

In the example illustrated in FIG. 19, the at least one third conductive layer 730 is illustrated adjacent to the antenna contact 231, but the disclosure is not limited thereto.

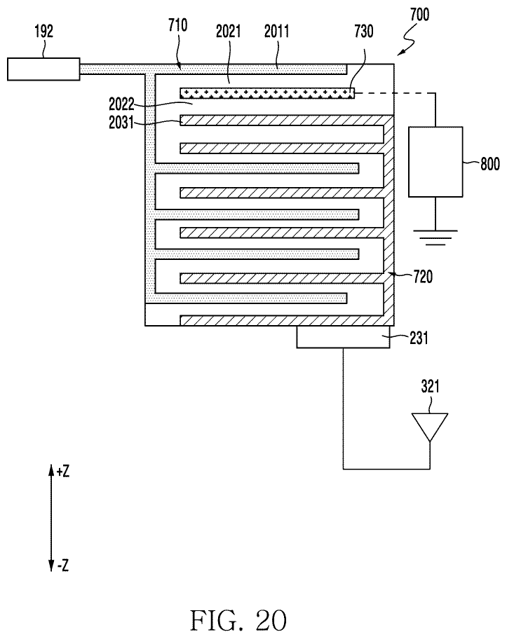

Referring to FIG. 20, at least one third conductive layer 730 may be closer to wireless communication circuitry 192 among the wireless communication circuitry 192 and an antenna contact 231.

For example, at least one first conductive layer 710 may include a plurality of conductive layers. The at least one first conductive layer 710 may include a sub conductive layer 2011 disposed on a front surface (e.g., a surface of a first connecting member 700 facing a +z direction) of the first connecting member 700. The sub conductive layer 2011 may be electrically connected to the wireless communication circuitry 192.

For example, the at least one third conductive layer 730 may be positioned below the sub conductive layer 2011 of the at least one first conductive layer 710 (e.g., in a −z direction). A first non-conductive layer 2021 may be disposed between the sub conductive layer 2011 and the at least one third conductive layer 730. For example, at least one second conductive layer 720 may include a sub conductive layer 2031 disposed below the at least one third conductive layer 730. A second non-conductive layer 2022 may be disposed between the at least one third conductive layer 730 and the sub conductive layer 2031 of the at least one second conductive layer 720. The first non-conductive layer 2021 and the second non-conductive layer 2022 may be connected to each other, or may also be separated from each other.

For example, the at least one third conductive layer 730 may at least partially form a second capacitor. For example, in a case that the at least one third conductive layer 730 includes a plurality of conductive layers, the at least one third conductive layer 730 may form the second capacitor. For example, in a case that the at least one third conductive layer 730 includes only a conductive layer, the second capacitor may be formed by the at least one third conductive layer 730 and the sub conductive layer 2011 and/or the sub conductive layer 2031 adjacent to the at least one third conductive layer 730.

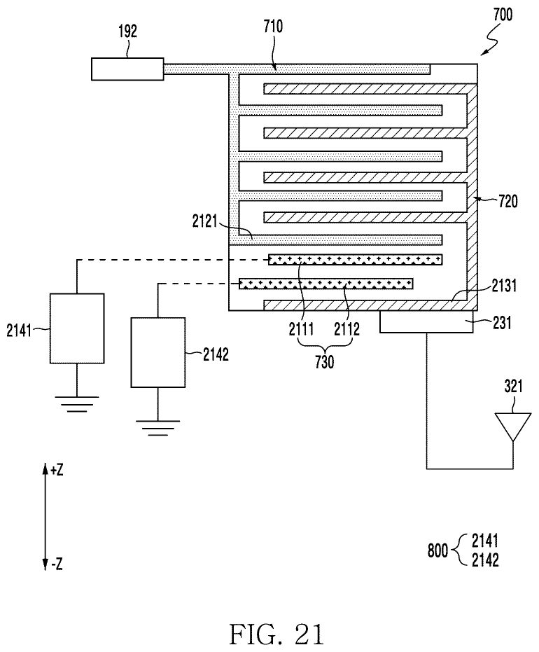

At least one third conductive layer 730 may include a plurality of layers. Referring to FIG. 21, the at least one third conductive layer 730 may include a first sub conductive layer 2111 and a second sub conductive layer 2112. The first sub conductive layer 2111 may be positioned below a sub conductive layer 2121 of at least one first conductive layer 710 (e.g., in a −z direction), and the second sub conductive layer 2112 may be positioned above a sub conductive layer 2131 of at least one second conductive layer 720 (e.g., in a +z direction). A second connecting member 800 may include a connecting member 2141 electrically connecting the first sub conductive layer 2111 to a ground and a connecting member 2142 electrically connecting the second sub conductive layer 2112 to the ground. The connecting member 2141 and/or the connecting member 2142 may include an inductor.

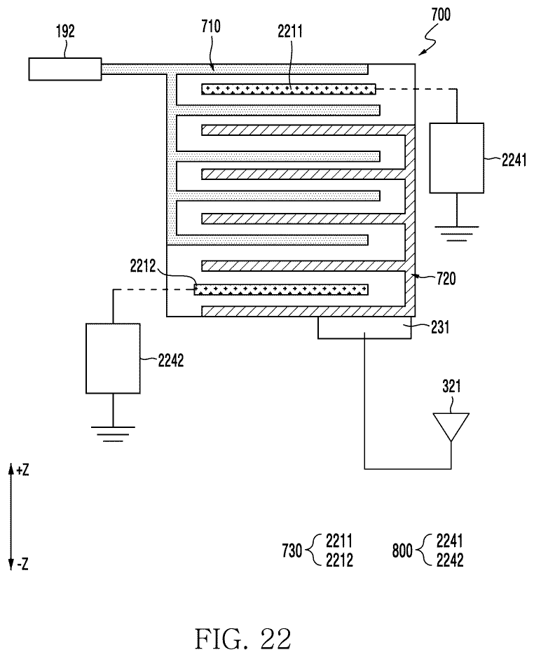

Referring to FIG. 22, at least one third conductive layer 730 may include a first sub conductive layer 2211 and a second sub conductive layer 2212. The first sub conductive layer 2211 may be adjacent to wireless communication circuitry 192, and the second sub conductive layer 2212 may be adjacent to an antenna contact 231. A second connecting member 800 may include a connecting member 2241 electrically connecting the first sub conductive layer 2211 to a ground and a connecting member 2242 electrically connecting the second sub conductive layer 2212 to the ground.

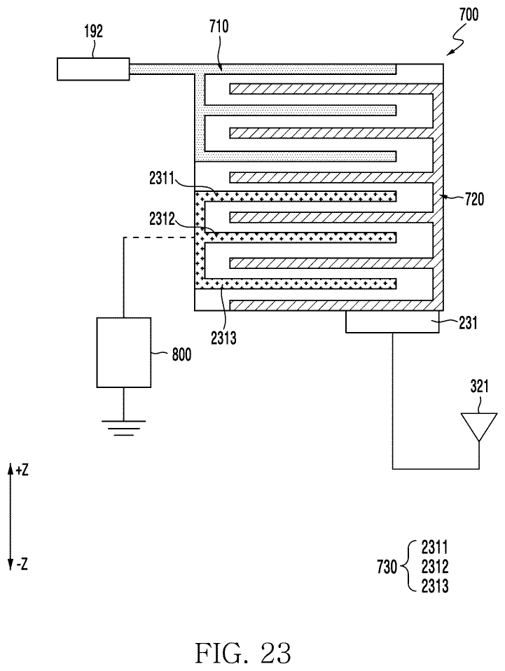

Referring to FIG. 23, at least one third conductive layer 730 may include three or more conductive layers. For example, the at least one third conductive layer 730 may include a first sub conductive layer 2311, a second sub conductive layer 2312, and/or a third sub conductive layer 2313. The first sub conductive layer 2311, the second sub conductive layer 2312, and/or the third sub conductive layer 2313 may at least partially form a second capacitor.

In addition, examples of the first connecting member 700 may vary. The first connecting member 700 may be configured to electrically connect the wireless communication circuitry 192 and the first conductive portion 321 and block static electricity.

FIGS. 24, 25, and 26 illustrate examples of a first connecting member including at least one fourth conductive layer according to various embodiments of the disclosure.

Referring to FIG. 24, as described above, a plurality of conductive layers of a first connecting member 700 may form a first capacitor configured to block static electricity. When static electricity flows through a first conductive portion 321, the first capacitor may be configured to block the static electricity. When static electricity is blocked by the first capacitor, charges may be accumulated in the first capacitor. Insulation breakdown between the conductive layers forming the first capacitor may be caused by the charges cumulatively accumulated in the first capacitor. Based on the insulation breakdown, arc discharging may be caused. The charges accumulated in the first capacitor may be discharged from the first capacitor by the arc discharging. In a case that the discharged charges are provided to wireless communication circuitry 192, damage to the wireless communication circuitry 192 may be caused.

According to an embodiment, since the first connecting member 700 includes a plurality of non-conductive layers and may be disposed on a printed circuit board, a pad-to-pad discharge may be difficult to occur. Referring to FIG. 24, the first connecting member 700 may include at least one fourth conductive layer 2410 for arc discharging. For example, the at least one fourth conductive layer 2410 may be electrically connected to at least one third conductive layer 730.

According to an embodiment, at least a portion of the at least one fourth conductive layer 2410 may be disposed to be exposed to the outside of the first connecting member 700. For example, as the at least one fourth conductive layer 2410 is disposed on an outer surface of the first connecting member 700, the at least a portion of the at least one fourth conductive layer 2410 may be exposed to the outside of the first connecting member 700. As illustrated in FIG. 24, the at least one fourth conductive layer 2410 electrically connected to the at least one third conductive layer 730 may be disposed on a side surface of the first connecting member 700 and a rear surface (e.g., a surface of the first connecting member 700 facing a −z direction) of the first connecting member 700. However, a disposition structure of the at least one fourth conductive layer 2410 according to the disclosure is not limited thereto.

Static electricity flowing through the first conductive portion 321 may be blocked by the first capacitor formed by the first connecting member 700. As the static electricity is blocked, charges may be accumulated in the first capacitor. In a case that the cumulatively accumulated charges cause arc discharging, the arc discharging may occur outside the first connecting member 700 through the at least one fourth conductive layer 2410 connected to the at least one third conductive layer 730. Due to the cumulated charges, insulation breakdown of air positioned outside the first connecting member 700 may be caused, and the charges may be discharged to the outside of the first connecting member 700 by the insulation breakdown. Since charges are discharged to the outside of the first connecting member 700 by arc discharging, damage to the wireless communication circuitry 192 due to arc discharging may be reduced.

The first connecting member 700 including the at least one fourth conductive layer 2410 exposed to the outside of the first connecting member 700 may vary.

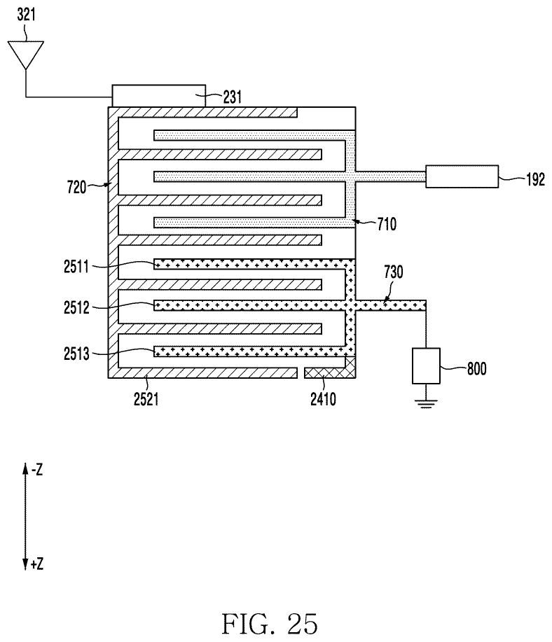

Referring to FIG. 25, at least one third conductive layer 730 may include a first sub conductive layer 2511, a second sub conductive layer 2512, and a third sub conductive layer 2513.

According to an embodiment, at least one fourth conductive layer 2410 may be connected to the second sub conductive layer 2512 of the at least one third conductive layer 730. The at least one fourth conductive layer 2410 may be disposed on an outer surface of a first connecting member 700. For example, the at least one fourth conductive layer 2410 may be disposed on a side surface of the first connecting member 700 and a rear surface of the first connecting member 700. A sub conductive layer 2521 of at least one second conductive layer 720 and a portion of the at least one fourth conductive layer 2410 may be disposed on a front surface (e.g., a surface of the first connecting member 700 facing a +z direction) of the first connecting member 700. The sub conductive layer 2521 and the at least one fourth conductive layer 2410 disposed on the rear surface of the first connecting member 700 may be spaced apart from each other.

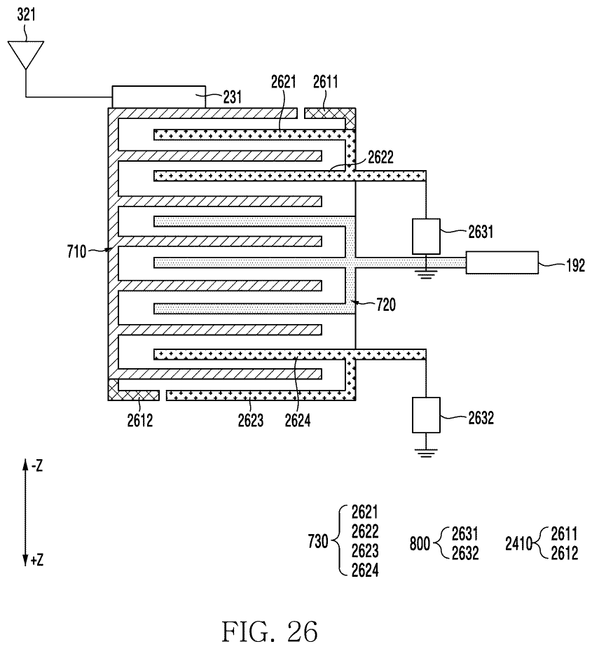

Referring to FIG. 26, at least one third conductive layer 730 may include a first sub conductive layer 2621 adjacent to a rear surface (e.g., a surface of a first connecting member 700 facing a −z direction) of the first connecting member 700 and a second sub conductive layer 2622 electrically connected to the first sub conductive layer 2621. A second connecting member 800 may include a connecting member 2631 electrically connecting the first sub conductive layer 2621 and the second sub conductive layer 2622 to a ground. The at least one third conductive layer 730 may include a third sub conductive layer 2623 adjacent to a front surface (e.g., a surface of the first connecting member 700 facing a +z direction) of the first connecting member 700 and a fourth sub conductive layer 2624 electrically connected to the third sub conductive layer 2623. For example, the third sub conductive layer 2623 may be disposed on the front surface. The second connecting member 800 may include a connecting member 2632 electrically connecting the third sub conductive layer 2623 and the fourth sub conductive layer 2624 to the ground.

For example, at least one fourth conductive layer 2410 exposed to the outside of the first connecting member 700 for arc discharging may include a first sub conductive layer 2611 and a second sub conductive layer 2612. The first sub conductive layer 2611 of the at least one fourth conductive layer 2410 maybe electrically connected to the first sub conductive layer 2621 and/or the second sub conductive layer 2622 of the at least one third conductive layer 730. The first sub conductive layer 2611 of the at least one fourth conductive layer 2410 may be disposed on a side surface of the first connecting member 700 and the rear surface of the first connecting member 700. When arc discharging occurs due to charges accumulated in a first capacitor, the charges may be discharged to the outside of the first connecting member 700 through the first sub conductive layer 2611 of the at least one fourth conductive layer 2410.

For example, the second sub conductive layer 2612 of the at least one fourth conductive layer 2410 may be electrically connected to the third sub conductive layer 2623 and/or the fourth sub conductive layer 2624 of the at least one third conductive layer 730. The second sub conductive layer 2612 of the at least one fourth conductive layer 2410 may be disposed on another side surface of the first connecting member 700 and the front surface of the first connecting member 700. When arc discharging occurs due to charges accumulated in a second capacitor, the charges may be discharged to the outside of the first connecting member 700 through the second sub conductive layer 2612 of the at least one fourth conductive layer 2410. In addition, a structure of the first connecting member 700 including the at least one fourth conductive layer 2410 may vary.

The technical problems to be achieved in this document are not limited to those described above, and other technical problems not mentioned herein will be clearly understood by those having ordinary knowledge in the art to which the disclosure belongs.

An electronic device 101 is disclosed. The electronic device 101 may include wireless communication circuitry 192. The electronic device 101 may include a frame 310 including a conductive portion 321, forming a portion of a periphery of the electronic device 101, configured to function as an antenna radiator. The electronic device 101 may include a first connecting member 700, including conductive layers and non-conductive layers alternatively stacked with the conductive layers, electrically connected to the wireless communication circuitry 192 and the conductive portion 321, respectively. The electronic device 101 may include a second connecting member 800, electrically connected to the first connecting member 700 and a ground of the electronic device 101, respectively. The first connecting member 700 may include at least one first conductive layer 710 electrically connected to the wireless communication circuitry 192, at least one second conductive layer 720, electrically connected to the conductive portion 321 and the at least one first conductive layer, respectively, and at least one third conductive layer 730 electrically connected to the ground through the second connecting member 800. The first connecting member 700 may be configured to function as a first capacitor to block static electricity flowing through the conductive portion 321.

According to an embodiment, the at least one first conductive layer 710 and the at least one second conductive layer 720 of the first connecting member 700 may provide a portion of an electrical path between the wireless communication circuitry 192 and the conductive portion 321.

According to an embodiment, the at least one first conductive layer 710 and the at least one second conductive layer 720 of the first connecting member 700 may be indirectly connected to each other.

According to an embodiment, the at least one first conductive layer 710 and the at least one second conductive layer 720 of the first connecting member 700 may be electrically isolated with respect to direct current.

According to an embodiment, the conductive portion 321 of the frame 310 may be configured to transmit and/or receive RF signals on a first frequency band. The second connecting member 800 may include an inductor. The at least one third conductive layer 730 of the first connecting member 700 may at least form a second capacitor. The second capacitor at least formed from the at least one third conductive layer 730 of the first connecting member 700 and the inductor of the second connecting member 800 may be configured to form a filter that has a pass band corresponding to a second frequency band different from the first frequency band.

According to an embodiment, the conductive portion of the frame may be configured to transmit and/or receive RF signals on a first frequency band. The second connecting member 800 may include an inductor. The at least one third conductive layer 730 of the first connecting member 700 may at least form a second capacitor. The second capacitor at least formed from the at least one third conductive layer 730 of the first connecting member 700 and the inductor of the second connecting member 800 may be configured to form a filter that has a stop band corresponding to the first frequency band.

According to an embodiment, the at least one third conductive layer 730 of the first connecting member 700 may include a first sub conductive layer and a second sub conductive layer. The second connecting member 800 may include a first inductor electrically connected to the first sub conductive layer, and a second inductor electrically connected to the second sub conductive layer.

According to an embodiment, the second connecting member 800 may include a plurality of sub connecting members including a capacitor or an inductor. The electronic device 101 may further include a switch circuit 1810 configured to electrically connect the at least one third conductive layer 730 to a sub connecting member among the plurality of sub connecting members.

According to an embodiment, the electronic device 101 may include at least one processor 120 including processing circuitry. The electronic device 101 may include memory 130 including one or more storage media storing instructions. The conductive portion 321 of the frame 310 may be configured to transmit and/or receive RF signals on a first frequency band. The instructions, when executed by the at least one processor 120 individually or collectively, may cause the electronic device 101 to control the switch circuit 1810, based on the first frequency band, such that the at least one third conductive layer 730 is connected to the sub connecting member among the plurality of sub connecting members.

According to an embodiment, a second capacitor at least formed from the at least one third conductive layer 730 and the sub connecting member among the plurality of sub connecting members may be configured to form a filter that has a pass band corresponding to a second frequency band different from the first frequency band, or a filter that has a stop band corresponding to the first frequency band.

According to an embodiment, the first connecting member 700 may include at least one fourth conductive layer 2410, electrically connected to the at least one third conductive layer 730, exposed to the outside of the first connecting member 700.

According to an embodiment, the at least one fourth conductive layer 2410 may be used for arc discharging by the static electricity.

According to an embodiment, the conductive portion 321 of the frame 310 may be configured to transmit and/or receive RF signals on a first frequency band. The frame 310 may include another conductive portion 322 configured to transmit and/or receive RF signals on a second frequency band, and a non-conductive portion 332 disposed between the conductive portion 321 and the other conductive portion 322. The second connecting member 800 may include an inductor. A second capacitor at least formed from the at least one third conductive layer 730 of the first connecting member 700 and the inductor of the second connecting member 800 may be configured to form a filter that has a stop band corresponding to the second frequency band.

According to an embodiment, the second connecting member 800 may include an inductor 910, a capacitor 920, or an electrical wire 930 or 940.

According to an embodiment, the first connecting member 700 may have a metal-insulator-metal (MIM) structure. The second connecting member 800 may be implemented in various ways, in addition to this.

According to an embodiment, the number of the at least one third conductive layer 730 may be based on a capacitance value of the first capacitor.

According to an embodiment, a size of the at least one third conductive layer 730 may be based on a capacitance value of the first capacitor.

An electronic device 101 is disclosed. The electronic device 101 may include wireless communication circuitry 192. The electronic device 101 may include a frame 310 including a conductive portion 321 that forms at least a portion of a periphery of the electronic device 101 and is configured to function as an antenna radiator. The electronic device 101 may include a support 340, at least partially surrounded by the frame 310, configured to function as a ground of the electronic device 101. The electronic device 101 may include a first connecting member 700, including conductive layers and non-conductive layers alternating with each other, electrically connected to the wireless communication circuitry 192 and the conductive portion 321, respectively. The electronic device 101 may include a second connecting member 800, electrically connected to the first connecting member 700 and the support 340, respectively. The first connecting member 700 may include at least one first conductive layer 710 electrically connected to the wireless communication circuitry 192, and at least one second conductive layer 720, electrically connected to the conductive portion 321 and the at least one first conductive layer 710, respectively. The electronic device 101 may include at least one third conductive layer 730, inserted into the first connecting member 700, electrically connected to the ground through the second connecting member 800. The at least one first conductive layer 710 and the at least one second conductive layer 720 may provide at least a portion of an electrical path between the wireless communication circuitry 192 and the conductive portion 321. The first connecting member 700 may be configured to function as a first capacitor to block static electricity flowing through the conductive portion 321.

According to an embodiment, the conductive portion 321 of the frame 310 may be configured to transmit and/or receive RF signals on a first frequency band. The second connecting member 800 may include an inductor. The at least one third conductive layer 730 of the first connecting member 700 may at least form a second capacitor. The second capacitor at least formed from the at least one third conductive layer 730 of the first connecting member 700 and the inductor of the second connecting member 800 may be configured to form a filter that has a pass band corresponding to a second frequency band different from the first frequency band.

According to an embodiment, the conductive portion of the frame may be configured to transmit and/or receive RF signals on a first frequency band. The second connecting member 800 may include an inductor. The at least one third conductive layer 730 of the first connecting member 700 may at least form a second capacitor. The second capacitor at least formed from the at least one third conductive layer 730 of the first connecting member 700 and the inductor of the second connecting member 800 may be configured to form a filter that has a stop band corresponding to the first frequency band.

The electronic device according to various embodiments may be one of various types of electronic devices. The electronic devices may include, for example, a portable communication device (e.g., a smartphone), a computer device, a portable multimedia device, a portable medical device, a camera, a wearable device, or a home appliance. According to an embodiment of the disclosure, the electronic devices are not limited to those described above.

It should be appreciated that various embodiments of the disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. It is to be understood that a singular form of a noun corresponding to an item may include one or more of the things unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” or “connected with” another element (e.g., a second element), it means that the element may be coupled with the other element directly (e.g., wiredly), wirelessly, or via a third element.

As used in connection with various embodiments of the disclosure, the term “module” may include a unit implemented in hardware, software, or firmware, and may interchangeably be used with other terms, for example, “logic,” “logic block,” “part,” or “circuitry”. A module may be a single integral component, or a minimum unit or part thereof, adapted to perform one or more functions. For example, according to an embodiment, the module may be implemented in a form of an application-specific integrated circuit (ASIC).

Various embodiments as set forth herein may be implemented as software (e.g., the program 140) including one or more instructions that are stored in a storage medium (e.g., internal memory 136 or external memory 138) that is readable by a machine (e.g., the electronic device 101). For example, a processor (e.g., the processor 120) of the machine (e.g., the electronic device 101) may invoke at least one of the one or more instructions stored in the storage medium, and execute it, with or without using one or more other components under the control of the processor. This allows the machine to be operated to perform at least one function according to the at least one instruction invoked. The one or more instructions may include a code generated by a compiler or a code executable by an interpreter. The machine-readable storage medium may be provided in the form of a non-transitory storage medium. Wherein, the term “non-transitory” simply means that the storage medium is a tangible device, and does not include a signal (e.g., an electromagnetic wave), but this term does not differentiate between a case in which data is semi-permanently stored in the storage medium and a case in which the data is temporarily stored in the storage medium.

According to an embodiment, a method according to various embodiments of the disclosure may be included and provided in a computer program product. The computer program product may be traded as a product between a seller and a buyer. The computer program product may be distributed in the form of a machine-readable storage medium (e.g., compact disc read only memory (CD-ROM)), or be distributed (e.g., downloaded or uploaded) online via an application store (e.g., PlayStore™), or between two user devices (e.g., smart phones) directly. If distributed online, at least part of the computer program product may be temporarily generated or at least temporarily stored in the machine-readable storage medium, such as memory of the manufacturer's server, a server of the application store, or a relay server.

According to various embodiments, each component (e.g., a module or a program) of the above-described components may include a single entity or multiple entities, and some of the multiple entities may be separately disposed in different components. According to various embodiments, one or more of the above-described components may be omitted, or one or more other components may be added.

Alternatively or additionally, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

No claim element is to be construed under the provisions of 35 U.S.C. § 112, sixth paragraph, unless the element is expressly recited using the phrase “means for” or “means.”

While the disclosure has been shown and described with reference to various embodiments thereof, it will be understood by those skilled in the art that various changes in form and details may be made therein without departing from the spirit and scope of the disclosure as defined by the appended claims and their equivalents.

What is claimed is:

1. An electronic device comprising:
wireless communication circuitry;
a frame including a conductive portion forming a portion of a periphery of the electronic device, wherein the conductive portion is configured to function as an antenna radiator;
a first connecting member, including conductive layers and non-conductive layers alternatively stacked with the plurality of conductive layers, electrically connected to the wireless communication circuitry and the conductive portion, respectively; and
a second connecting member, electrically connected to the first connecting member and a ground of the electronic device, respectively,
wherein the first connecting member includes:
at least one first conductive layer electrically connected to the wireless communication circuitry,
at least one second conductive layer, electrically connected to the conductive portion and the at least one first conductive layer, respectively, and
at least one third conductive layer electrically connected to the ground through the second connecting member, and
wherein the first connecting member is configured to function as a first capacitor to block static electricity flowing through the conductive portion.

2. The electronic device of claim 1, wherein the at least one first conductive layer and the at least one second conductive layer of the first connecting member provide a portion of an electrical path between the wireless communication circuitry and the conductive portion.

3. The electronic device of claim 1, wherein the at least one first conductive layer and the at least one second conductive layer of the first connecting member are indirectly connected to each other.

4. The electronic device of claim 3, wherein the at least one first conductive layer and the at least one second conductive layer of the first connecting member are electrically isolated with respect to direct current.

5. The electronic device of claim 1,
wherein the conductive portion of the frame is configured to transmit or receive radio frequency (RF) signals on a first frequency band,
wherein the second connecting member includes an inductor,
wherein the at least one third conductive layer of the first connecting member at least forms a second capacitor, and
wherein the second capacitor at least formed from the at least one third conductive layer of the first connecting member and the inductor of the second connecting member are configured to form a filter that has a pass band corresponding to a second frequency band different from the first frequency band.

6. The electronic device of claim 1,
wherein the conductive portion of the frame is configured to transmit or receive RF signals on a first frequency band,
wherein the second connecting member includes an inductor,
wherein the at least one third conductive layer of the first connecting member at least forms a second capacitor, and
wherein the second capacitor at least formed from the at least one third conductive layer of the first connecting member and the inductor of the second connecting member are configured to form a filter that has a stop band corresponding to the first frequency band.

7. The electronic device of claim 1,
wherein the at least one third conductive layer of the first connecting member includes a first sub conductive layer and a second sub conductive layer, and
wherein the second connecting member includes:
a first inductor electrically connected to the first sub conductive layer, and
a second inductor electrically connected to the second sub conductive layer.

8. The electronic device of claim 1,
wherein the second connecting member includes a plurality of sub connecting members including a capacitor or an inductor, and
wherein the electronic device further comprises a switch circuit configured to electrically connect the at least one third conductive layer to a sub connecting member among the plurality of sub connecting members.

9. The electronic device of claim 8, further comprising:
at least one processor including processing circuitry; and
memory including one or more storage media storing instructions,
wherein the conductive portion of the frame is configured to transmit or receive RF signals on a first frequency band, and
wherein the instructions, when executed by the at least one processor individually or collectively, cause the electronic device to control the switch circuit, based on the first frequency band, such that the at least one third conductive layer is connected to the sub connecting member among the plurality of sub connecting members.

10. The electronic device of claim 9, wherein a second capacitor at least formed from the at least one third conductive layer and the sub connecting member among the plurality of sub connecting members are configured to form a filter that has a pass band corresponding to a second frequency band different from the first frequency band, or a filter that has a stop band corresponding to the first frequency band.

11. The electronic device of claim 1, wherein the first connecting member includes at least one fourth conductive layer, electrically connected to the at least one third conductive layer, exposed to outside of the first connecting member.

12. The electronic device of claim 11, wherein the at least one fourth conductive layer is used for arc discharging by the static electricity.

13. The electronic device of claim 1,
wherein the conductive portion of the frame is configured to at least one of transmit or receive radio frequency (RF) signals on a first frequency band,
wherein the frame includes:
another conductive portion configured to at least one of transmit or receive RF signals on a second frequency band, and
a non-conductive portion disposed between the conductive portion and the other conductive portion,
wherein the second connecting member includes an inductor, and
wherein a second capacitor at least formed from the at least one third conductive layer of the first connecting member and the inductor of the second connecting member are configured to form a filter that has a stop band corresponding to the second frequency band.

14. The electronic device of claim 1, wherein the second connecting member includes an inductor, a capacitor, or an electrical wire.

15. The electronic device of claim 1, wherein the first connecting member has a metal-insulator-metal (MIM) structure.

16. The electronic device of claim 1, wherein a number of the at least one third conductive layer is based on a capacitance value of the first capacitor.

17. The electronic device of claim 1, wherein a size of the at least one third conductive layer is based on a capacitance value of the first capacitor.

18. The electronic device of claim 1, further comprising:
an antenna contact through which the at least one second conductive layer and the conductive portion are electrically connected.

19. An electronic device comprising:
wireless communication circuitry;
a frame including a conductive portion, forming at least a portion of a periphery of the electronic device, configured to function as an antenna radiator;
a support, at least partially surrounded by the frame, configured to function as a ground of the electronic device;
a first connecting member, including conductive layers alternating with non-conductive layers, electrically connected to the wireless communication circuitry and the conductive portion, respectively; and
a second connecting member, electrically connected to the first connecting member and the support, respectively,
wherein the first connecting member includes:
at least one first conductive layer electrically connected to the wireless communication circuitry, and
at least one second conductive layer, electrically connected to the conductive portion and the at least one first conductive layer, respectively,
wherein the electronic device comprises at least one third conductive layer, inserted into the first connecting member, electrically connected to the ground through the second connecting member,
wherein the at least one first conductive layer and the at least one second conductive layer of the first connecting member provide at least a portion of an electrical path between the wireless communication circuitry and the conductive portion, and
wherein the first connecting member is configured to function as a first capacitor to block static electricity flowing through the conductive portion.

20. The electronic device of claim 19,
wherein the conductive portion of the frame is configured to transmit or receive radio frequency (RF) signals on a first frequency band,
wherein the second connecting member includes an inductor,
wherein the at least one third conductive layer of the first connecting member at least forms a second capacitor, and
wherein the second capacitor at least formed from the at least one third conductive layer of the first connecting member and the inductor of the second connecting member are configured to form a filter that has a pass band corresponding to a second frequency band different from the first frequency band.
